(19) United States
(12) Patent Application Publication
(10) Pub. No.: US 2026/0330076 A1
(43) Pub. Date: Oct. 22, 2026

(54) SYSTEM

(71) Applicant: SoftBank Group Corp., Tokyo (JP)

(72) Inventor: Eisuke YAMAZAKI, Tokyo (JP)

(73) Assignee: SoftBank Group Corp., Tokyo (JP)

(21) Appl. No.: 19/650,338

(22) Filed: Apr. 17, 2026

(30) Foreign Application Priority Data
Apr. 21, 2025 (JP) 2025-069975

(51) Int. Cl. G06F 30/12

(52) U.S. Cl. CPC G06F 30/12

(57) ABSTRACT

The present invention relates to a system that automatically generates a plurality of product design proposals using generative AI based on an application, a size, a material, a color, and other constraint conditions input by a user, and automatically outputs a script for three-dimensional model generation usable in three-dimensional modeling software based on a proposal selected by the user. As a result, even a user who does not have specialized three-dimensional modeling knowledge can select an optimal one from among various design options in a short time and easily, and automatically generate a specific three-dimensional model, making it possible to significantly improve efficiency in initial design and prototyping processes of new product development.

### CROSS-REFERENCE TO RELATED APPLICATION

The present application claims priority to and incorporates by reference the entire contents of Japanese Patent Application No. 2025-069975 filed in Japan on Apr. 21, 2025.

### BACKGROUND OF THE INVENTION

### 1. Field of the Invention

The technology of this disclosure relates to a system.

### 2. Description of the Related Art

Japanese Patent Application Laid-open No. 2022-180282 discloses a persona chatbot control method executed by at least one processor, comprising: receiving a user utterance, adding the user utterance to a prompt containing instructions related to the character of the chatbot, encoding the prompt, inputting the encoded prompt into a language model, and generating a chatbot utterance in response to the user utterance.

A problem to be solved by the present invention is the problem that, in a planning stage of a new product, when creating a specific three-dimensional model from a huge number of product concepts and ideas, advanced three-dimensional modeling technology, specialized knowledge, and further a great deal of time and effort, which have been conventionally required, are necessary, that is, the problem that it is difficult for a person in charge of planning to quickly and accurately embody his/her own ideas as a three-dimensional model, and to efficiently perform visualization, verification, and further proposals inside and outside the company and prototyping. In particular, the present invention is to realize significant efficiency improvement and labor saving in initial design and prototyping processes in conventional new product development by providing an environment in which a plurality of design options reflecting various design requirements and constraint conditions are generated in a short time and a user can easily select and modify them, and further by automatically outputting a script for three-dimensional model generation usable in three-dimensional modeling software based on the selection result, thereby enabling even a user without specialized knowledge to intuitively and efficiently create a three-dimensional model.

### SUMMARY OF THE INVENTION

A means for solving the problem according to the present invention is to provide a system comprising a user input unit, a generative AI processing unit, and a three-dimensional model generation unit, wherein the user input unit has a function of receiving design requirements including an application, a size, a material, a color, and other constraint conditions of a product from a user, the generative AI processing unit has a function of receiving the design requirements received from the user input unit as input data, automatically generating a plurality of product design proposals based on the design requirements, and imparting, to each of the design proposals, features reflecting a shape optimized for the application, the specified material and color, and the other constraint conditions, and the three-dimensional model generation unit automatically outputs a script for three-dimensional model generation usable in three-dimensional modeling software based on contents of a design proposal selected by the user from among the design proposals generated by the generative AI processing unit, and the script automatically generates a three-dimensional model reflecting the specified size, color, and material information, whereby even if the user does not have specialized three-dimensional modeling technology or knowledge, the user can select an optimal one from among various design options in a short time and easily, and automatically generate a specific three-dimensional model, thereby significantly improving efficiency and realizing labor saving in initial design and prototyping processes of new product development.

### BRIEF DESCRIPTION OF THE DRAWINGS

FIG. 1 is a conceptual diagram showing an example configuration of a data processing system according to the first embodiment;

FIG. 2 is a conceptual diagram showing an example of main functions of a data processing device and a smart device according to the first embodiment;

FIG. 3 is a conceptual diagram showing an example configuration of a data processing system according to the second embodiment;

FIG. 4 is a conceptual diagram showing an example of main functions of a data processing device and smart glasses according to the second embodiment;

FIG. 5 is a conceptual diagram showing an example configuration of a data processing system according to the third embodiment;

FIG. 6 is a conceptual diagram showing an example of main functions of a data processing device and a headset-type terminal according to the third embodiment;

FIG. 7 is a conceptual diagram showing an example configuration of a data processing system according to the fourth embodiment;

FIG. 8 is a conceptual diagram showing an example of main functions of a data processing device and a robot according to the fourth embodiment;

FIG. 9 shows an emotion map where multiple emotions are mapped; and

FIG. 10 shows an emotion map where multiple emotions are mapped.

### DETAILED DESCRIPTION OF THE PREFERRED EMBODIMENTS

Hereinafter, an example of an embodiment of the system related to the technology disclosed herein will be described with reference to the attached drawings.

First, the terminology used in the following description will be explained.

In the following embodiments, a processor indicated by reference numeral (hereinafter simply referred to as “processor”) may be a single computing device or a combination of multiple computing devices. The processor may be a single type of computing device or a combination of multiple types of computing devices. Examples of computing devices include a CPU (Central Processing Unit), GPU (Graphics Processing Unit), GPGPU (General-Purpose computing on Graphics Processing Units), APU (Accelerated Processing Unit), among others.

In the following embodiments, a RAM (Random Access Memory) indicated by reference numeral is a memory where information is temporarily stored and used as a work memory by the processor.

In the following embodiments, a storage indicated by reference numeral is one or more non-volatile storage devices for storing various programs and parameters. Examples of non-volatile storage devices include flash memory (SSD (Solid State Drive)), magnetic disks (e.g., hard disks), or magnetic tapes, among others.

In the following embodiments, a communication I/F (Interface) indicated by reference numeral is an interface including a communication processor and an antenna, among others. The communication I/F manages communication between multiple computers. Examples of communication standards applicable to the communication I/F include wireless communication standards such as 5G (5th Generation Mobile Communication System), Wi-Fi (registered trademark), or Bluetooth (registered trademark), among others.

In the following embodiments, “A and/or B” means “at least one of A and B.” In other words, “A and/or B” means it may be only A, only B, or a combination of A and B. Moreover, when expressing three or more items connected by “and/or,” the same concept as “A and/or B” applies.

### First Embodiment

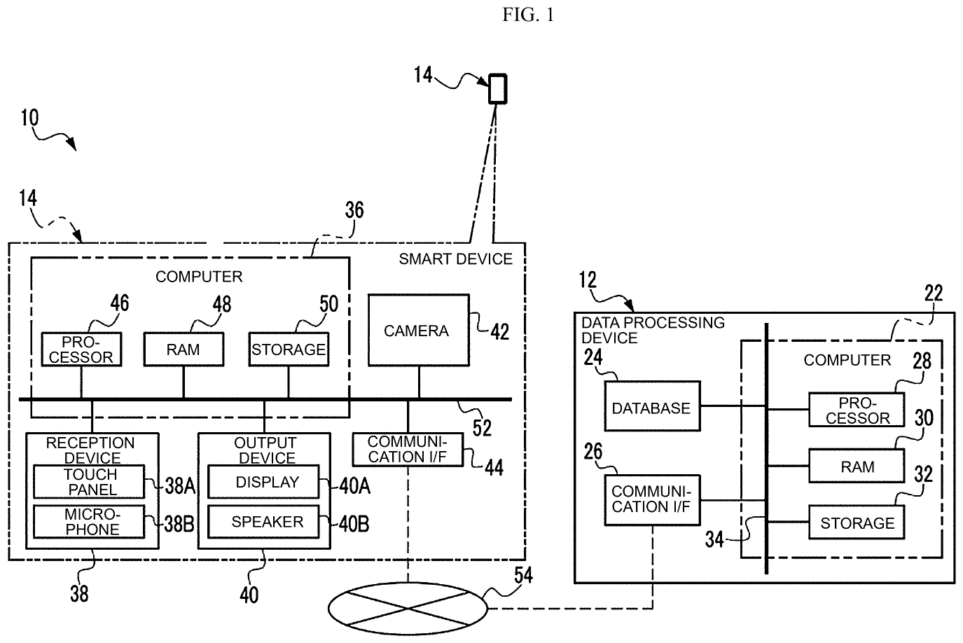

FIG. 1 Shows an Example Configuration of a Data Processing System 10 According to the first embodiment.

As shown in FIG. 1, the data processing system 10 comprises a data processing device 12 and a smart device 14. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The smart device 14 comprises a computer 36, a reception device 38, an output device 40, a camera 42, and a communication I/F 44. The computer 36 comprises a processor 46, RAM 48, and storage 50. The processor 46, RAM 48, and storage 50 are connected to a bus 52. The reception device 38, output device 40, camera 42, and communication I/F 44 are also connected to the bus 52.

The reception device 38 comprises a touch panel 38A and a microphone 38B, among others, and accepts user input. The touch panel 38A accepts user input by detecting contact from an indicating object (e.g., a pen or finger). The microphone 38B accepts user input by detecting the user's voice. The control unit 46A in the processor 46 sends data indicating user input accepted by the touch panel 38A and microphone 38B to the data processing device 12. In the data processing device 12, the specific processing unit 290 acquires data indicating user input.

The output device 40 comprises a display 40A and a speaker 40B, among others, and presents data to the user 20 by outputting it in a perceptible form (e.g., audio and/or text). The display 40A displays visible information such as text and images according to instructions from the processor 46. The speaker 40B outputs audio according to instructions from the processor 46. The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors.

The communication I/F 44 is connected to the network 54. The communication I/F 44 and 26 manage the exchange of various information between the processor 46 and the processor 28 via the network 54.

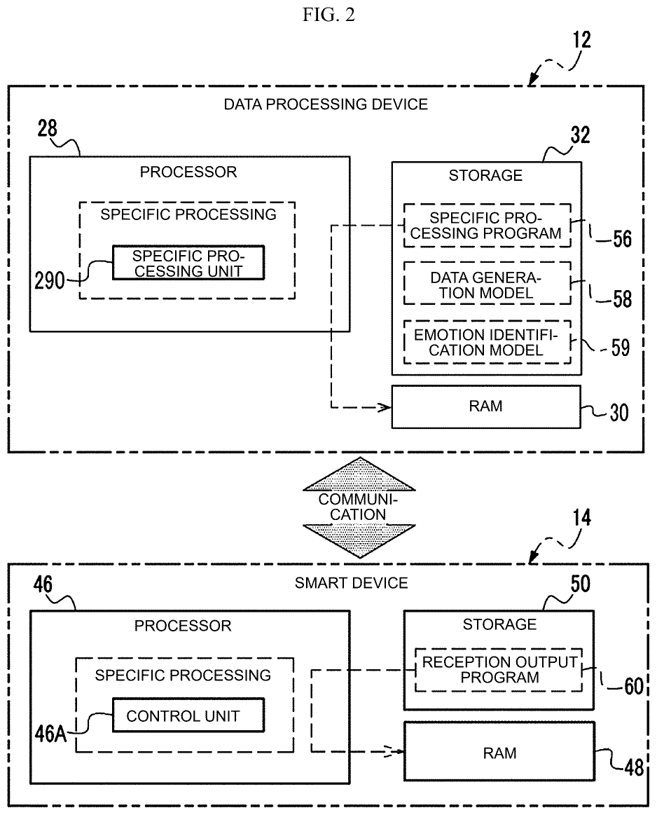

FIG. 2 shows an example of the main functions of the data processing device 12 and the smart device 14.

As shown in FIG. 2, specific processing is performed in the data processing device 12 by the processor 28. The storage 32 stores a specific processing program 56. The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, and various estimations and predictions related to the user's emotions are performed, but it is not limited to such examples. Furthermore, emotion estimation and prediction may include, for example, emotion analysis.

In the smart device 14, reception output processing is performed by the processor 46. The storage 50 stores a reception output program 60. The reception output program 60 is used in conjunction with the specific processing program 56 by the data processing system 10. The processor 46 reads the reception output program 60 from the storage 50 and executes it on the RAM 48. The reception output processing is realized by the processor 46 operating as a control unit 46A according to the reception output program 60 executed on the RAM 48. The smart device 14 may also have similar data generation models and emotion identification models as the data generation model 58 and emotion identification model 59, and perform the same processing as the specific processing unit 290 using these models. The reception output processing is realized by the processor 46 operating as the control unit 46A according to the reception output program 60 executed on the RAM 48.

Other devices besides the data processing device 12 may have the data generation model 58.

For example, a server device (e.g., a generation server) may have the data generation model 58.

In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.). Next, an example of processing by the data processing system 10 according to the first embodiment will be described.

### (Example 1)

The flow of the specific processing in Example 1 will be described. Each part of the system described below is realized by the data processing device 12 and the smart device 14. Additionally, the data processing device 12 is referred to as a “server,” and the smart device 14 is referred to as a “terminal.”

### (Embodiment for Carrying out the Present Invention)

An embodiment of the present invention will be described more specifically and in detail. The system of the present invention is composed of a terminal and a server, and is configured such that the terminal provides a user interface, and the server is responsible for generative AI processing and three-dimensional model generation processing. As the terminal, any information processing apparatus capable of network connection, such as a personal computer, a tablet terminal, a smartphone, a wearable terminal, and further a dedicated terminal for business use, can be used. As the server, computing resources having computing capability of generative AI and three-dimensional model generation capability, such as a cloud server, an on-premises server, a distributed processing server, and an edge server, are used. Specifically. The present system adopts a client-server architecture. The present system uses a secure encryption protocol for communication between the terminal and the server. The present server includes a parallel computing cluster using GPUs. The present server executes each processing unit as a containerized microservice. The present configuration centralizes inference processing of the generative AI having a high calculation load on the server side. The present configuration significantly relaxes hardware requirements on the terminal side. The present system suppresses battery consumption of the terminal. The present system dramatically improves processing speed. The present server distributes requests to a plurality of computing nodes via a load balancer. The present server maintains a stable response time even against a rapid increase in traffic. The present system makes a large language model and an image generation model resident on a memory. The present system minimizes inference latency. The present system enables rendering processing of a three-dimensional model to be executed on the server side as well. The present system transmits only lightweight drawing commands to the terminal. The present system reduces consumption of a network bandwidth. The present system is applied to an initial design phase in the manufacturing industry. The present system significantly shortens a designer's trial and error time. The present system enables even a non-expert to perform advanced three-dimensional design. The present system improves resource management efficiency of computer technology itself.

First, a user input unit on the terminal includes various input means such as a GUI, voice input, touch operation, pen input, or import of an external file. For example, a user can specify extremely diverse applications, such as “a small storage case used on a desk”, “a weather-resistant bench used outdoors”, “a safe toy for children”, “a housing for an electronic device”, “a portable foldable container”, “an instrument storage box for medical use”, and “an assembly-type fixture for an exhibition”, as an application by natural language, choices, or uploading of an image or a drawing. Regarding a size, specific numerical input (e.g., height 10 cm, width 5 cm, depth 8 cm), relative size (e.g., a size that can accommodate A 4 paper, a palm size), and further functional constraints such as “withstand a maximum weight of up to 2 kilograms” can be input. Regarding a material, various choices such as plastic, metal, wood, glass, ceramic, composite material, recycled material, heat-resistant material, and antibacterial material can be specified from viewpoints of an application, cost, environmental load, workability, strength, weight, texture, and the like. Regarding a color, a single color, a plurality of colors, a gradation, a pattern, a brand color, a color matching code (e.g., PANTONE code), and further abstract instructions such as “a bright color preferred by children” and “a calm tone” are possible. As other constraint conditions, extremely diverse and complex conditions such as “with a drawer”, “stackable”, “waterproof specification”, “impact resistance”, “assembly type”, “disassemblable and washable”, “safety standard compliant”, “cost upper limit”, “environmental consideration”, “insert a specific logo or design”, and “have compatibility with a specific part” can be specified plurally and simultaneously. Specifically. The user input unit of the present terminal converts the input diverse data into structured data. The present input unit tokenizes text input by natural language. The present input unit converts a token sequence into a multidimensional word embedding vector. The present input unit inputs image data to a convolutional neural network. The present input unit extracts a visual feature vector from the image. The present input unit normalizes numerical data and categorical data. The present input unit encodes the normalized data as a numerical vector. The present input unit combines vectors of these different modalities. The present input unit generates a combined high-dimensional tensor. The present input unit packages this high-dimensional tensor as a payload for transmission to the server. The present process converts a human's ambiguous intention into a strict mathematical expression processable by a computer. The present process dramatically improves analysis accuracy by the subsequent generative AI. The present system detects a loss or a contradiction of the input data. The present system automatically generates a prompt prompting the user to re-input when a contradiction is detected. The present system ensures quality of the input data. The present system is applied to a field of furniture design and prototyping of industrial products. The present system transmits the user's diverse requirements to the system without omission. The present system realizes a technical improvement of a data input interface.

The terminal transmits these input data to the server. A generative AI processing unit is provided on the server side, where a generative AI analyzes the input design requirements. The generative AI makes a comprehensive judgment by linking a plurality of AI modules such as natural language processing, image recognition, structural optimization, material property inference, past design database reference, user history analysis, similar case search, trend analysis, cost simulation, and environmental load evaluation. For example, if the application is a “storage case”, the number and arrangement of drawers, presence or absence of a handle, a stacking structure, a lock mechanism, presence or absence of a partition plate, an anti-slip shape on a bottom surface, an opening/closing method of a lid (slide type, flip-up type, magnet type, etc.), a thickness of a material, a load capacity, cost, mass productivity, and the like are automatically designed. For example, if it is an “outdoor bench”, a height of a seat surface, an angle of a backrest, strength of legs, a weather-resistant coating, an anchor fixing structure, a fall prevention design, maintainability, disassembly and transportability, corrosion resistance of a material, ultraviolet degradation countermeasures, dimension optimization based on a user's physique distribution, and the like are automatically determined, and a plurality of design variations are generated. For example, if it is a “toy”, roundness of corners considering children's safety, a minimum part size for preventing accidental ingestion, ease of assembly, color variations based on color psychology, addition of educational elements, durability, washability, part replaceability, legal regulation compliance, and the like are also automatically reflected in the design. Specifically. The present generative AI processing unit includes a composite AI model combining a large language model based on a transformer architecture and a graph neural network. The present AI model receives the high-dimensional tensor received from the terminal as input data. The present input data includes, for example, a 768-dimensional text embedding vector and a 512-dimensional image feature vector. The present AI model calculates a dependency relationship between respective elements in the input data using a self-attention mechanism. The present AI model dynamically weights importance of the application and the constraint conditions. The present AI model outputs graph structure data representing a connection relationship between nodes and edges in a three-dimensional space. The present output data includes, for example, a 1024-row by 3-column floating-point tensor indicating three-dimensional coordinates of each part. The present output data includes a probability distribution vector indicating a material of each part. The present processing unit determines whether or not a maximum value of the output probability distribution vector exceeds a predetermined threshold value. When the threshold value is exceeded, the present processing unit passes the material as a determined material to a subsequent structural optimization module. The present structural optimization module automatically executes a simulation based on a finite element method. The present structural optimization module specifies a stress concentration location. The present structural optimization module automatically increases a wall thickness of the specified location. The present process is a non-conventional mathematical approach that does not rely on human intuition. The present process autonomously ensures physical validity of the design inside the computer. The present system prevents wasteful consumption of computing resources. The present system dramatically improves quality and safety of the generated three-dimensional model. The present system is applied to automatic design of building members and customized design of medical devices.

The generative AI generates a plurality of design proposals optimized for the application and the constraint conditions while also referring to past design data, design patterns, a material property database, a user's input history, industry standards, legal regulations, cost data, environmental load data, user evaluation data, trend information, and the like. For example, it is possible to preferentially propose a shape or a structure that has obtained a high evaluation for a similar application in the past, or to automatically generate a design proposal that also considers strength, workability, cost, environmental load, and procurability of a material, a processing method (injection molding, cutting, additive manufacturing, etc.), and a surface treatment (painting, plating, printing, laser processing, etc.). Furthermore, when “ease of carrying” is emphasized, a folding mechanism, a weight reduction design, an arrangement of a handle, compactness during storage, durability, balance, analysis of a user's holding manner and carrying operation, and the like can be automatically reflected in the design. For example, if it is a “medical instrument storage box”, sterility, airtightness, a label affixing space, flexibility of a partition, an impact absorbing structure upon dropping, opening/closing frequency durability, chemical resistance, washability, identifiability by color coding, and the like are also automatically reflected in the design. Specifically. The present generative AI cooperates with an external database using a retrieval-augmented generation technology. The present generative AI searches a vector database using the input requirement vector as a query. The present vector database holds past design data as points on a high-dimensional vector space. The present generative AI calculates a cosine similarity between the query vector and each vector in the database. The present generative AI extracts design data having a higher similarity as a context. The present generative AI combines the extracted context with an input tensor. The present generative AI inputs the combined tensor to a decoder network. The present decoder network outputs parameters of a plurality of design proposals in parallel. The present output includes, for example, a numerical array indicating a volume, a surface area, and an estimated manufacturing cost of each design proposal. The present generative AI applies an evaluation function to each output design proposal. The present evaluation function calculates a weighted linear sum of respective indices of strength, cost, and environmental load. The present generative AI selects a predetermined number of design proposals having higher evaluation scores as final candidates. The present process searches for an optimal solution from a vast design space at high speed. The present process fundamentally improves a conventional design process depending on human memory and experience. The present process realizes data-driven objective design proposal generation. The present system optimizes calculation efficiency. The present system reduces memory usage. The present system is applied to weight reduction design of aerospace parts and aerodynamic optimization design of automobile parts.

The plurality of design proposals generated by the generative AI processing unit on the server are transmitted to the terminal. On the terminal, information from extremely diverse viewpoints, such as features, an appearance image, dimensions, material information, a functional description, a cost estimate, an environmental load evaluation, a mass productivity evaluation, a user evaluation prediction, legal regulation compliance, an assembly procedure, a disassembly procedure, maintainability, customizability, part replaceability, and brand image compatibility of each proposal, is presented. For example, a three-dimensional preview image of each proposal, a convenience evaluation by application, a cost estimate, an environmental load evaluation, an assembly animation, a disassembly animation, a parts list, a material list, a processing method list, a recommended production method, a recommended distribution method, a recommended package proposal, and the like are also presented simultaneously. The user can select an optimal design proposal while referring to these pieces of information. Specifically. The present server converts three-dimensional structure data of the generated design proposal into a lightweight polygon mesh format. The present server serializes the converted mesh data and metadata as a payload in a data description language format. The present server transmits the serialized data to the terminal using an asynchronous communication protocol. The present terminal expands the received data on a memory. The present terminal renders a three-dimensional preview image in real time using a built-in graphics processing unit. The present terminal recalculates a drawing matrix in accordance with a user's viewpoint change operation. The present terminal dynamically draws a shadow and a reflection by driving a pixel shader on a screen. The present terminal overlay-displays numerical values of cost and environmental load as infographics. The present terminal draws an evaluation score of each design proposal as a vertex coordinate vector of a radar chart. The present process efficiently visualizes a heavy calculation result on the server side on the terminal side. The present process minimizes consumption of a network bandwidth. The present process dramatically improves responsiveness of a user interface. The present system captures a user's selection operation with an event listener. The present system immediately feeds back an identifier of the selected design proposal to the server. The present system is applied to an order receiving system for custom products in electronic commerce and a parts procurement platform between companies. The present system eliminates a delay in information presentation. The present system improves display control technology of a computer.

When the user selects a design proposal, the terminal transmits the selection information to the server, and a three-dimensional model generation unit on the server automatically generates a script for three-dimensional model generation usable in three-dimensional modeling software based on contents of the selected design proposal. This script for three-dimensional model generation is output, for example, in a script format of an open-source three-dimensional modeling tool (e.g., Python script, JSON format, STEP format, STL format, OBJ format, etc.), and has contents for automatically generating a three-dimensional model reflecting information such as the specified size, material, color, structure, and function. For example, if it is a storage case, an outer frame, a drawer, a handle, an uneven structure for stacking, a lock mechanism, a partition plate, an anti-slip on a bottom surface, an opening/closing mechanism of a lid, a label space, a divided structure for each part, an assembly procedure, a disassembly procedure, and the like are automatically arranged, and material setting reflecting dimensions and material information is also automatically performed. If it is a chair, a seat surface, a backrest, legs, a reinforcing structure, a coating layer, an anchor fixing portion, a fall prevention portion, a joint for disassembly and transport, an access panel for maintenance, dimension optimization based on a user's physique distribution, thickness and strength setting for each material, and the like are automatically generated. If it is a toy, roundness considering safety, division of parts, an assembly structure, educational elements, color variations, part replaceability, washability, legal regulation compliance, arrangement of a brand logo, engraving of a user name, and the like are automatically designed. Specifically. The present three-dimensional model generation unit includes an autoregressive code generation neural network. The present neural network receives a parameter group of the selected design proposal as an input vector. The present input vector includes, for example, a floating-point array indicating dimensions of each part and one-hot encoding of a categorical variable indicating a material. The present neural network constructs an abstract syntax tree stepwise based on these inputs. The present neural network serializes the constructed abstract syntax tree into a text character string in accordance with syntax rules of a specific script language. The present output data is, for example, text data of a script including a generation function of vertex coordinates and a call of a Boolean operation. The present processing unit test-executes the generated script in a virtual environment. The present processing unit automatically detects a runtime error of the script and self-intersection of the generated mesh. The present processing unit executes a feedback loop for correcting a corresponding line of the script when an error is detected. The present process completely eliminates a conventional process in which a human manually operates design software. The present process realizes automation of code generation and verification inside a computer. The present system shortens a generation speed of the script to a millisecond unit. The present system guarantees geometric accuracy of the generated three-dimensional model. The present system is applied to construction of a digital twin and automatic generation of assets for a virtual space. The present system advances automation technology of data processing.

Furthermore, a parameter setting function (e.g., dimensions, color, material, presence or absence of parts, function addition/deletion) that the user can finely adjust later, an automatic generation function of a plurality of variations, a strength analysis and cost estimation function by application, an environmental load evaluation function, an assembly/disassembly animation generation function, a parts list/material list automatic generation function, a processing method recommendation function, a mass productivity evaluation function, a user evaluation prediction function, a legal regulation compliance check function, and the like can also be incorporated into the script for three-dimensional model generation. Also in generating these scripts, the generative AI comprehensively considers the user's application and constraint conditions, past design data, material properties, cost data, environmental load data, legal regulation data, user evaluation data, and the like, and automatically determines an optimal three-dimensional model generation procedure. Specifically. The present three-dimensional model generation unit dynamically implements a concept of parametric modeling in the script. The present processing unit defines dimensions and a positional relationship of each part not as fixed values but as a combination of variables and mathematical formulas. The present processing unit constructs a directed acyclic graph representing a dependency relationship between variables in the script. The present processing unit scans the directed acyclic graph when the user changes a specific variable. The present processing unit embeds code of a constraint solver that recalculates all related variables in a chained manner into the script. The present generative AI adds a finite element mesh division algorithm for strength analysis as a subroutine in the script. The present generative AI includes a lookup table for cost calculation in the script in a data description language format. The present process completes advanced simulation and redesign with the generated script alone. The present process reduces a degree of dependence on external software. The present system optimizes memory consumption in an execution environment of the script. The present system minimizes redrawing latency when a parameter is changed. The present system reduces a calculation load when the user performs fine adjustment of the design in a local environment. The present system is applied as a design simulation teaching material in an educational institution or a distribution format of open-source hardware. The present system expands program generation capability of a computer.

In addition, even when the user performs input with different applications and conditions a plurality of times, the generative AI can learn past input history and selection tendencies, and automatically generate a proposal and a design proposal optimized for each user. For example, for a user who has designed a “storage case” a plurality of times in the past, a preferred shape, function, material, color, cost range, brand image, and the like can be learned, and a more personalized proposal can be automatically made. Furthermore, even when an additional request or a correction instruction (e.g., “add one more drawer”, “change the position of the handle”, “change the material to metal”, “change the color to blue”, “add a logo”, etc.) is input for the design proposal selected by the user, the generative AI can immediately analyze the contents and automatically regenerate a new design proposal and a script for three-dimensional model generation reflecting the corrected contents. Specifically. The present system records an action history for each user in a time-series database. The present system inputs the recorded time-series data to a recurrent neural network. The present neural network continuously updates a latent feature vector representing the user's design preference. The present system automatically adds this latent feature vector as a context to a prompt of the generative AI. The present system finely adjusts weights of a model using a reinforcement learning algorithm with whether or not the user finally adopted the design proposal as a reward signal. The present system executes a natural language processing pipeline that extracts a change difference when an additional request is input as text. The present pipeline outputs a pair of a parameter to be changed and a new value as dictionary data in a key-value format. The present generative AI merges this dictionary data into an existing design parameter group. The present generative AI differentially compiles only a corresponding part of the script for three-dimensional model generation based on the merged parameter group. The present process avoids regeneration of the entire script. The present process significantly reduces consumption of computing resources. The present process shortens a turnaround time from a correction instruction to result presentation to a millisecond order. The present system provides a personalized design experience. The present system is applied as a tool for supporting repetitive correction work of a professional designer. The present system improves adaptive learning capability of a computer.

Furthermore, for example, even when the user uploads external design data, an image, a drawing, a sketch, CAD data, three-dimensional scan data, or the like, the generative AI can analyze these data, automatically perform redesign and optimization in accordance with the specified application and constraint conditions, and generate a new design proposal and a script for three-dimensional model generation. For example, by uploading three-dimensional scan data of an existing product and giving instructions such as “add a drawer based on this shape”, “change the material”, “enlarge the dimensions”, and “have compatibility with a specific part”, the generative AI can automatically perform optimization design and output a script for three-dimensional model generation. Specifically. The present external data import unit expands the uploaded three-dimensional scan data on a memory as a point cloud tensor. The present processing unit executes preprocessing for converting the point cloud tensor into a voxel grid. The present processing unit extracts a spatial feature map from the voxel data using a three-dimensional convolutional neural network. The present processing unit inputs the extracted feature map to an encoder of the generative AI. The present generative AI combines the input feature map and the user's text instruction vector using a cross-attention mechanism. The present generative AI outputs a signed distance function of a new shape from the combined representation vector. The present output data is a three-dimensional array of continuous scalar values indicating how far each point in a space is from an object surface. The present processing unit applies a marching cubes method to this signed distance function. The present processing unit automatically extracts an optimized new polygon mesh. The present process reconstructs a geometrically accurate solid model from noisy scan data. The present process completely automates reverse engineering by human manual work. The present system improves accuracy of data conversion. The present system dramatically shortens a processing time from several hours to several seconds. The present system is applied to alternative manufacturing of a damaged part and digital restoration of a cultural property. The present system fundamentally improves three-dimensional data processing capability of a computer.

As described above, in the embodiment of the present invention, by adopting a configuration in which the user input unit is realized by the terminal, and the generative AI processing unit and the three-dimensional model generation unit are realized by the server, a calculation load on the terminal side can be reduced, and advanced design proposal generation and three-dimensional model generation processing utilizing a high-performance generative AI can be realized on the server side. The terminal can be configured by a personal computer, a tablet terminal, a smartphone, a wearable terminal, a dedicated terminal for business use, or the like, and the server can be configured by a cloud server, an on-premises server, a distributed processing server, an edge server, or the like. Specifically. The present system realizes optimal task division between edge computing and cloud computing. The present terminal executes only a lightweight front-end application. The present terminal specializes in capturing a user's input event and drawing processing. The present server uses dedicated hardware equipped with a tensor computing unit. The present server executes inference of a large-scale model having billions of parameters at high speed. The present system serializes data transmitted and received between the terminal and the server into a binary format. The present system minimizes a size of a communication payload. The present system enhances tolerance against network delay and packet loss. The present system batch-processes a plurality of inference requests on the server side. The present system maximizes a memory bandwidth of a parallel computing processor. The present system improves throughput. The present configuration guarantees stable operation even in an environment where a bandwidth is limited, such as a mobile line. The present configuration maximizes utilization efficiency of hardware resources. The present system is applied to a globally deployed design collaboration platform. The present system solves technical problems of data synchronization and computing resource management in a distributed system. The present system improves performance of the entire computer network.

As described above, according to the embodiment of the present invention, by combining advanced automatic design and automatic three-dimensional model generation processing on the server side with generative AI as a core and an intuitive user interface on the terminal side, it is possible to realize a system capable of significantly improving the efficiency of an initial design and a prototyping process in conventional new product development, and enabling even a user without specialized knowledge to easily and quickly automatically generate diverse three-dimensional models. Specifically, the system integrates a design space search algorithm and a machine learning model. The system automatically searches for an optimal solution of design parameters using a gradient descent method. The system incorporates user feedback into a loss function. The system continuously improves output accuracy of the model. The system executes topology optimization of the generated three-dimensional model in the background. The system mathematically derives a shape that ensures necessary strength while eliminating material waste. This process generates a non-intuitive optimal shape that is difficult to reach by human intuition. The system seamlessly connects a data pipeline from design to manufacturing. The system eliminates data format conversion errors. The system shortens a lead time required for prototype manufacturing from several weeks to several minutes. The system dramatically reduces development costs. The system is applied to system linkage with a cloud manufacturing service. The system functions as a fundamental technology for on-demand manufacturing. The system brings about a technical innovation of autonomous design generation by a computer, rather than mere operational efficiency improvement. The system expands an application range of an information processing apparatus to a core process of a manufacturing industry.

### (System Configuration)

The system according to the present embodiment includes a user input unit, a data transmission unit, a generative AI processing unit, a design proposal presentation unit, a user selection unit, a three-dimensional model generation unit, a script output unit, a history management unit, and an external data import unit. The user input unit has a function for a user to input an application, a size, a material, a color, and other constraint conditions of a product on a terminal, and can specify diverse applications such as “a small storage case used on a desk”, “a weather-resistant bench used outdoors”, “a safe toy for children”, “a housing for an electronic device”, “a portable foldable container”, “an instrument storage box for medical use”, and “an assembly-type fixture for an exhibition” by means such as natural language, choices, an image, a drawing, voice input, a touch operation, pen input, and external file import. Furthermore, regarding the size, specific or abstract instructions such as “height 10 cm, width 5 cm, depth 8 cm”, “a size that accommodates A4 paper”, and “withstands a maximum weight of up to 2 kilograms” are possible, and regarding the material, diverse choices such as “plastic”, “metal”, “wood”, “glass”, “composite material”, “recycled material”, “heat-resistant material”, and “antibacterial material” can be specified. Regarding the color, instructions such as “single color”, “multiple colors”, “gradation”, “brand color”, “color matching code”, “bright color preferred by children”, and “calm tone” are possible, and as the other constraint conditions, a plurality of conditions such as “with a drawer”, “stackable”, “waterproof specification”, “impact resistance”, “assembly type”, “disassemblable and washable”, “safety standard compliant”, “cost upper limit”, “environmental consideration”, “inserting a specific logo or design”, and “having compatibility with a specific part” can be specified simultaneously. The data transmission unit plays a role of transmitting all the information input by the user input unit to a server, and also performs encryption of network communication, data format conversion, retransmission control at the time of a transmission error, consistency check of input data, and the like. Specifically, each module of the system operates as an independent process on a memory space. The system executes data transfer between the modules at high speed using inter-process communication. The user input unit aggregates the input data of diverse modalities into a single data object. The user input unit passes the voice input to a voice recognition engine to convert it into text data. The user input unit samples a trajectory of the touch operation as array data of two-dimensional coordinates. The data transmission unit serializes the aggregated data object into a byte stream. The data transmission unit encrypts the byte stream using a transport layer security protocol. The data transmission unit adds a checksum to verify data integrity. The data transmission unit temporarily stores the data in a local cache when detecting a network disconnection. The data transmission unit automatically executes a retransmission process in the background after communication recovery. This process completely prevents data loss even in an unstable network environment. This process improves fault tolerance of the system. The system performs a type check and a range check of the input data in advance on the terminal side. The system prevents invalid data from being transmitted to the server. The system suppresses wasteful calculation resource consumption of the server. The system is applied to a requirement input terminal from a field worker in a smart factory. The system provides a robust data collection infrastructure.

The generative AI processing unit operates on the server, analyzes the design requirements transmitted from the user, and automatically generates a plurality of product design proposals having an optimal shape, structure, material, color, and function according to the application and the constraint conditions. For example, in the case of a “storage case”, the number and arrangement of drawers, the presence or absence of a handle, a stacking structure, a lock mechanism, the presence or absence of a partition plate, an anti-slip shape on a bottom surface, an opening/closing method of a lid, a thickness of a material, a load capacity, cost, mass productivity, and the like are automatically designed, and in the case of an “outdoor bench”, a height of a seat surface, an angle of a backrest, strength of legs, a weather-resistant coating, an anchor fixing structure, a fall prevention design, maintainability, disassembly and transportability, corrosion resistance of a material, an ultraviolet degradation countermeasure, dimension optimization based on a user's physique distribution, and the like are automatically determined, and a plurality of design variations are generated. In the case of a “toy”, roundness of corners considering children's safety, a minimum part size for preventing accidental ingestion, ease of assembly, color variations based on color psychology, addition of educational elements, durability, washability, part replaceability, legal regulation compliance, and the like are also reflected in the automatic design. The generative AI processing unit generates a plurality of design proposals optimized for the application and the constraint conditions while also referring to past design data, design patterns, a material property database, a user's input history, industry standards, legal regulations, cost data, environmental load data, user evaluation data, trend information, and the like, and for example, when emphasizing “portability”, a folding mechanism, a weight reduction design, an arrangement of a handle, compactness during storage, durability, balance, analysis of a user's holding method and carrying operation, and the like are reflected in the automatic design. Specific examples of a prompt sentence to be read by the generative AI include “Application: small storage case used on a desk, Size: height 10 cm, width 5 cm, depth 8 cm, Material: plastic, Color: white, Conditions: with a drawer, stackable, cost upper limit 1000 yen, emphasis on mass productivity, environmentally friendly design, brand logo arranged on a side surface, shape that a user can carry with one hand, assembly type, disassemblable and washable, anti-slip provided on a bottom surface”, “Application: weather-resistant bench used outdoors, Size: two adults can sit, Material: composite of metal and wood, Color: natural wood and black, Conditions: anchor fixing structure, fall prevention design, ultraviolet degradation countermeasure, disassembly and transportability, emphasis on maintainability, cost upper limit 50,000 yen, design matching a brand image”, and the like. Specifically, the generative AI processing unit inputs the input prompt sentence into a natural language processing model. The model divides the prompt sentence into subword units and converts them into an array of token IDs. The model passes the token ID array through an embedding layer to acquire a dense vector representation. The model calculates contextual relevance between respective tokens using a multi-head attention mechanism. The model extracts, for example, a strong relevance between “outdoors” and “weather resistance” as an attention weight matrix. The processing unit supplies this context vector to a diffusion model as a conditioning input. The diffusion model starts from a random noise tensor and removes noise stepwise. The diffusion model generates three-dimensional voxel data matching the conditioning vector. The output data is, for example, a three-dimensional grid having a resolution of 64×64×64, and each voxel has a continuous value from 0 to 1 indicating an occupation probability. The processing unit performs threshold processing on this voxel data to extract a solid shape. The processing unit calculates a volume and a surface area of the extracted shape and inputs them to a cost simulation module. The simulation module calculates an estimated manufacturing cost by referring to a material unit price database. This process deterministically derives a specific three-dimensional shape satisfying physical constraints from abstract requirements by text. This process reduces a cognitive load of a human designer to zero. The system outputs a plurality of variations in a few seconds by parallelizing the generation process. The system is applied to exterior design of personal mobility and automatic generation of custom-made furniture. The system technically proves an execution capability of a creative task by a computer.

The design proposal presentation unit transmits the plurality of design proposals generated by the generative AI processing unit to the terminal, and presents information from diverse viewpoints, such as features, an appearance image, dimensions, material information, a functional description, a cost estimate, an environmental load evaluation, a mass productivity evaluation, a user evaluation prediction, legal regulation compliance, an assembly procedure, a disassembly procedure, maintainability, customizability, part replaceability, and brand image compliance of each proposal on the terminal. For example, a three-dimensional preview image, a convenience evaluation by application, a cost estimate, an environmental load evaluation, an assembly animation, a disassembly animation, a parts list, a material list, a processing method list, a recommended production method, a recommended distribution method, a recommended package proposal, and the like are also presented simultaneously. The user selection unit has a function for the user to select an optimal proposal from among the plurality of presented design proposals, and for example, the user can make a selection while comparing and examining the three-dimensional preview while rotating and scaling it, comparing detailed information, cost, environmental load, mass productivity, legal regulation compliance, and the like of each proposal, and referring to the user evaluation prediction and the brand image compliance. Furthermore, it is also possible to input an additional request or a correction instruction (for example, “add one more drawer”, “change the position of the handle”, “change the material to metal”, “change the color to blue”, “add a logo”, and the like) for the proposal selected by the user, and this information is transmitted to the generative AI processing unit again, and a new design proposal reflecting correction contents is automatically generated. Specifically, the design proposal presentation unit caches multidimensional evaluation data received from the server on a memory of the terminal. The presentation unit calls a web-based graphics interface to draw the three-dimensional preview on a canvas. The presentation unit hooks an event of a user's touch swipe or mouse drag. The presentation unit updates a quaternion of a virtual camera based on a delta value of the event. The presentation unit re-renders a scene using the updated camera matrix. The user selection unit monitors a state of a UI component on a screen. The selection unit acquires a unique ID of a specific design proposal when the user presses a selection button for the proposal. When an additional correction instruction is input, the selection unit analyzes the text with a natural language processing module. The selection unit extracts a pair of a parameter name to be corrected and a changed value. The selection unit asynchronously transmits this difference data to the server in a data description language format. This process provides a seamless user experience without accompanying a screen reload. This process optimizes a processor usage rate of the terminal. The system reduces an overhead of network communication. The system is applied to an interactive design review system and a customer-participatory product customization tool. The system improves interface technology between a human and a computer.

The three-dimensional model generation unit automatically generates a script for three-dimensional model generation usable in three-dimensional modeling software based on contents of the design proposal selected by the user. For example, it is output in a script format of an open-source three-dimensional modeling tool (Python script, JSON format, STEP format, STL format, OBJ format, etc.), and has contents for automatically generating a three-dimensional model reflecting information such as the specified size, material, color, structure, and function. For example, in the case of a storage case, an outer frame, a drawer, a handle, an uneven structure for stacking, a lock mechanism, a partition plate, an anti-slip on a bottom surface, an opening/closing mechanism of a lid, a label space, a divided structure for each part, an assembly procedure, a disassembly procedure, and the like are automatically arranged, and material setting reflecting dimensions and material information is also automatically performed. In the case of a chair, a seat surface, a backrest, legs, a reinforcing structure, a coating layer, an anchor fixing portion, a fall prevention portion, a joint for disassembly and transport, an access panel for maintenance, dimension optimization based on a user's physique distribution, thickness and strength setting for each material, and the like are automatically generated. In the case of a toy, roundness considering safety, division of parts, an assembly structure, educational elements, color variations, part replaceability, washability, legal regulation compliance, arrangement of a brand logo, engraving of a user name, and the like are automatically designed. The script output unit transmits the script for three-dimensional model generation generated by the three-dimensional model generation unit to the terminal, and enables the user to download it or import it into external three-dimensional modeling software. For example, the user can download the script and edit and utilize it in their own design department, or directly transmit it to an external three-dimensional printer or a processing contractor. Specifically, the three-dimensional model generation unit maps a parameter group of the design proposal to an internal abstract syntax tree. The generation unit generates a node defining a geometric primitive of each part. The generation unit constructs an edge defining a Boolean operation between parts. The generation unit traverses this abstract syntax tree by depth-first search. The generation unit sequentially generates a code character string according to syntax rules of a target language in a process of the traversal. The generation unit outputs, for example, a function group calling a three-dimensional processing library as text. The script output unit buffers the generated text data on a memory as a character encoding file. The output unit applies a hash function to this file to generate a checksum for falsification prevention. The output unit transmits the file and the checksum to the terminal as multipart form data. The terminal saves the received data in a local storage. This process expresses a complex three-dimensional shape as lightweight text data. This process dramatically reduces a data transfer amount from a gigabyte unit to a kilobyte unit. The system saves storage capacity. The system makes the generated script easily manageable by a version control system. The system is applied to sharing of design data in a distributed development environment and direct data input to an automatic manufacturing line. The system fundamentally improves efficiency of data representation and transfer.

The history management unit centrally manages a user's input history, selection history, generated design proposals, scripts for three-dimensional model generation, download history, correction history, tendency data for each user, and the like, and for example, for a user who has designed a “storage case” a plurality of times in the past, can learn a preferred shape, function, material, color, cost range, brand image, and the like, and automatically make a more personalized proposal. When the user uploads external design data, an image, a drawing, a sketch, CAD data, three-dimensional scan data, or the like, the external data import unit analyzes these data, automatically performs redesign and optimization according to the specified application and constraint conditions, and can generate a new design proposal and a script for three-dimensional model generation. For example, by uploading three-dimensional scan data of an existing product and giving instructions such as “add a drawer based on this shape”, “change the material”, “enlarge the dimensions”, and “make it compatible with a specific part”, the generative AI can automatically perform optimization design and output a script for three-dimensional model generation. Specifically, the history management unit adopts a hybrid storage combining a relational database and a non-relational database. The management unit stores structured parameter data in a table. The management unit saves a script and an image, which are unstructured data, in a document store. The management unit accumulates a user's operation log as time-series data. The system inputs this time-series data to a long short-term memory network. The network probabilistically predicts the user's next design requirement. The external data import unit parses the uploaded design data as a boundary representation model. The import unit extracts topology information and geometry information from the boundary representation model. The import unit converts the extracted information into graph structure data. The generative AI applies a graph convolutional network to this graph structure data. The generative AI updates coordinates of a node so as to satisfy the specified constraint conditions while retaining features of the existing shape. This process maximizes reusability of existing assets. This process eliminates a calculation cost associated with design from scratch. The system optimizes a query response time of the database. The system continuously improves inference accuracy of the machine learning model. The system is applied to reverse engineering work and digital archiving of legacy products. The system improves a technical framework for data management and reuse.

As described above, the system according to the present embodiment includes the user input unit, the data transmission unit, the generative AI processing unit, the design proposal presentation unit, the user selection unit, the three-dimensional model generation unit, the script output unit, the history management unit, and the external data import unit, and by each unit operating in cooperation, realizes a system capable of allowing a user to easily select an optimal one from among diverse design options in a short time and automatically generate a specific three-dimensional model even if the user does not have specialized three-dimensional modeling technology or knowledge. Examples of the prompt sentence to be read by the generative AI include those comprehensively including the application, size, material, color, and conditions, such as “Application: instrument storage box for medical use, Size: width 30 cm, height 20 cm, depth 15 cm, Material: antibacterial plastic, Color: white, Conditions: emphasis on sterility, airtightness, label attachment space, flexibility of partition, shock absorption structure upon dropping, opening/closing frequency durability, chemical resistance, washability, distinguishability by color coding, cost upper limit 3000 yen, legal regulation compliance”. Specifically, the system loosely couples each processing unit via an asynchronous message queue. The system adopts an event-driven architecture. The system dynamically scales out an instance of a specific module when a load concentrates on the module. The system keeps a throughput of the entire system constant. The generative AI analyzes the input comprehensive prompt sentence with a natural language understanding model. The model extracts each condition as a key-value pair. The model converts the extracted condition group into an input format of a constraint satisfaction problem. The system specifies a solution region of a parameter space that simultaneously satisfies all the conditions using a constraint solver. The system generates a plurality of initial seeds from within this solution region by random sampling. The system executes optimization by a gradient method starting from each seed. This process mathematically resolves a trade-off between conflicting constraint conditions. This process automatically derives a Pareto optimal solution. The system enables optimization in a multidimensional space exceeding human cognitive limits. The system maximizes hardware utilization efficiency by dynamic allocation of calculation resources. The system is applied to strict standard-compliant design of medical devices and optimization design of aircraft parts. The system improves integrated processing capability of a computer system.

### (Implementation Steps)

Step 1: User Requirement Input A user inputs an application, a size, a material, a color, and other constraint conditions of a product using a user input unit on a terminal. For example, as the application, “a small storage case used on a desk”, “a weather-resistant bench used outdoors”, “a safe toy for children”, “a housing for an electronic device”, “a portable foldable container”, “an instrument storage box for medical use”, “an assembly-type fixture for an exhibition”, and the like can be specified by diverse methods such as natural language, choices, an image, a drawing, voice input, a touch operation, pen input, and external file import. The size can be input including specific numerical values, relative sizes, and functional constraints, and a plurality of materials, colors, and other constraint conditions can also be specified in detail simultaneously. Specifically, the terminal binds an event listener to each input field of a user interface. The terminal captures a user's keystroke or mouse click in real time. The terminal immediately executes validation using a regular expression on the input character string. When an image file is dropped, the terminal analyzes a file header to verify validity of a format. The terminal reads valid image data as a byte array on a memory. The terminal maps these input data to a key-value type data structure. When detecting completion of the input, the terminal serializes the data structure into a character string. This process guarantees formal consistency of the input data on the terminal side. This process dramatically reduces an error occurrence rate in subsequent communication and server processing. The system keeps a response speed of the input interface in a millisecond unit. The system eliminates a user's input stress. The system normalizes data from diverse input devices into a unified format. The system is applied to a multi-platform compatible design application. The system improves technical reliability of data input processing.
Step 2: Input Data Transmission The terminal transmits all data input by the user to the server via a data transmission unit. At this time, encryption of network communication, data format conversion, retransmission control at the time of a transmission error, consistency check of input data, and the like are also performed simultaneously. Specifically. The terminal stores a serialized character string in a body of a communication request. The terminal adds an authentication token and a content type to a request header. The terminal calls a communication protocol stack to generate a packet. The terminal executes a handshake to establish a secure communication channel with the server. The terminal sends out the generated packet via a network interface card. The terminal waits for a response from the server after the transmission. The terminal attempts retransmission while gradually extending a retransmission interval using an exponential backoff algorithm when there is no response within a predetermined timeout period. The server decrypts a payload of the received packet. The server verifies structural consistency of the data using a schema validator. This process completely prevents eavesdropping and falsification of data on a communication path by a cryptographic algorithm. This process enhances robustness of the system against packet loss and network delay. The system suppresses wasteful consumption of communication resources. The system is applied to a secure cloud-based design platform. The system improves data transfer technology between computer networks.
Step 3: Design Proposal Generation by Generative AI The generative AI processing unit on the server analyzes the design requirements transmitted from the user, and automatically generates a plurality of product design proposals having an optimal shape, structure, material, color, and function according to the application and the constraint conditions. For example, in the case of a “storage case”, the number and arrangement of drawers, the presence or absence of a handle, a stacking structure, a lock mechanism, the presence or absence of a partition plate, an anti-slip shape on a bottom surface, an opening/closing method of a lid, a thickness of a material, a load capacity, a cost, mass productivity, and the like are automatically designed, and in the case of an “outdoor bench”, a height of a seat surface, an angle of a backrest, strength of a leg portion, a weather-resistant coating, an anchor fixing structure, a fall prevention design, maintainability, disassembly transportability, corrosion resistance of a material, an ultraviolet degradation countermeasure, dimensional optimization based on a user's physique distribution, and the like are automatically determined, and a plurality of design variations are generated. Specific examples of a prompt sentence to be read by the generative AI include “Application: small storage case used on a desk, Size: height 10 cm, width 5 cm, depth 8 cm, Material: plastic, Color: white, Conditions: with drawer, stackable, cost upper limit 1000 yen, emphasis on mass productivity, environmentally friendly design, brand logo arranged on side surface, shape that user can carry with one hand, assembly type, disassemblable and washable, anti-slip provided on bottom surface”. Specifically. The server enqueues the received requirement data into an input queue of an inference engine. The inference engine dequeues the data from the queue, pads the data into a tensor for batch processing, and puts the data together. The inference engine transfers this batch tensor to a memory of a parallel arithmetic processor. The generative AI maps the requirement text to a 768-dimensional latent space vector using a transformer-based encoder. The generative AI inputs this latent vector as a condition to a generator of a generative adversarial network. The generator generates a three-dimensional voxel grid. The discriminator determines whether the generated voxel grid satisfies physical constraints and specified conditions, and outputs a score. The generative AI repeats a generation loop while fine-tuning weights of the generator until the score exceeds a predetermined threshold. The output data is, for example, a structured array including vertex coordinates, a normal vector, and a material identifier of each design proposal. This process uses a learning result of a complex probability distribution in a high-dimensional space. This process realizes flexible shape generation that cannot be described by a rule-based program. The system maximizes parallel computing capability. The system significantly shortens inference time. The system is applied to automation of industrial design and procedural generation of game assets. The system dramatically improves arithmetic processing efficiency of a computer.
Step 4: Presentation and Selection of Design Proposal The plurality of design proposals generated by the generative AI processing unit are transmitted to the terminal via a design proposal presentation unit, and information from diverse viewpoints, such as features, an appearance image, dimensions, material information, a functional description, a cost estimate, an environmental load evaluation, a mass productivity evaluation, a user evaluation prediction, legal regulation compliance, an assembly procedure, a disassembly procedure, maintainability, customizability, part replaceability, and brand image compliance of each proposal, is presented on the terminal. The user selects an optimal design proposal while referring to a three-dimensional preview image, a convenience evaluation by application, a cost estimate, an environmental load evaluation, an assembly animation, a disassembly animation, a parts list, a material list, a processing method list, a recommended production method, a recommended distribution method, a recommended package proposal, and the like. Specifically, the design proposal presentation unit of the system receives a plurality of pieces of design proposal data output from the generative AI processing unit. The design proposal data is configured as a multidimensional tensor including voxel data representing a three-dimensional shape and each attribute value. The design proposal presentation unit temporarily stores the received multidimensional tensor in a main memory. The design proposal presentation unit analyzes the stored multidimensional tensor. The design proposal presentation unit generates three-dimensional preview image data based on an analysis result. The design proposal presentation unit transmits the generated three-dimensional preview image data to the terminal. The terminal receives the three-dimensional preview image data via a network interface. The terminal renders the received three-dimensional preview image data on a display. In this rendering process, the terminal utilizes a parallel arithmetic cluster using a GPU. The terminal calculates vertex coordinate data and normal vector data of a polygon mesh. The terminal executes a real-time shading process based on a calculation result. The terminal calculates a luminance value of each pixel based on a position of a light source and a viewpoint vector. The system receives a selection operation from the user via a touch panel or a mouse. The system extracts an identifier corresponding to the selected design proposal. The system transmits the extracted identifier to the server. By this process, the system realizes narrowing down of design proposals accurately reflecting the user's intention. The system enables a preview display of a high-definition three-dimensional model while suppressing consumption of a communication band. This technology is applicable to diverse use cases such as a product design process in the manufacturing industry and a prototype evaluation in the architectural field.
Step 5: Input of Additional Request/Correction Instruction and Regeneration The user can input an additional request or a correction instruction (for example, “add one more drawer”, “change position of handle”, “change material to metal”, “change color to blue”, “add logo”, etc.) for the selected design proposal, and such information is transmitted to the generative AI processing unit again, and a new design proposal reflecting correction contents is automatically generated. Specific examples of a prompt sentence to be read by the generative AI include “Application: storage case, Size: height 10 cm, width 5 cm, depth 8 cm, Material: metal, Color: blue, Conditions: increase drawers to two stages, change position of handle to center, add brand logo”. Specifically, the terminal of the system receives the additional request and the correction instruction from the user. The terminal inputs the received natural language text to a natural language processing model. The natural language processing model is a large-scale language model based on a transformer architecture. Input data to the natural language processing model is an embedded vector sequence of words. The embedded vector sequence is expressed as, for example, a 512-dimensional floating-point number array. As a specific example of the input data, vector data converted from a text “add one more drawer” can be cited. As another specific example, vector data converted from a text “change material to metal” can be cited. The natural language processing model calculates a contextual dependency of the input vector sequence using a self-attention mechanism. The natural language processing model calculates an attention score matrix indicating a degree of association between respective words. The natural language processing model updates a feature vector based on the calculated attention score matrix. The natural language processing model inputs the updated feature vector to a fully connected layer. The natural language processing model outputs a correction intention vector based on a calculation result. The correction intention vector is expressed as, for example, a coordinate value on a 1024-dimensional latent space. As a specific example of the output data, a vector including a structure change flag instructing addition of a drawer can be cited. As another specific example, a vector including a material ID instructing a material change can be cited. The generative AI processing unit inputs the output correction intention vector to a subsequent three-dimensional shape generation model. The three-dimensional shape generation model generates new three-dimensional voxel data using a generative adversarial network. The three-dimensional shape generation model combines an existing shape tensor and the correction intention vector, and executes a three-dimensional convolution operation. By this process, the system automatically executes an accurate three-dimensional shape change from an ambiguous natural language instruction of the user. The system significantly shortens time required for trial and error by a designer. This technology is applicable to fields requiring rapid prototyping, such as furniture design and customization of industrial products.
Step 6: Automatic Generation of Script for Three-Dimensional Model Generation Based on contents of the design proposal finally selected by the user, the three-dimensional model generation unit on the server automatically generates a script for three-dimensional model generation usable in three-dimensional modeling software. For example, it is output in a script format (Python script, JSON format, STEP format, STL format, OBJ format, etc.) of an open-source three-dimensional modeling tool, and has contents for automatically generating a three-dimensional model reflecting information such as the specified size, material, color, structure, and function. Specifically, the three-dimensional model generation unit of the system acquires three-dimensional voxel data of the selected design proposal. The three-dimensional model generation unit converts the acquired three-dimensional voxel data into polygon mesh data. In this conversion process, the three-dimensional model generation unit executes a marching cubes algorithm. The three-dimensional model generation unit extracts an isosurface in a voxel space. The three-dimensional model generation unit extracts vertex coordinates and surface connection information of the generated polygon mesh. The three-dimensional model generation unit inputs the extracted geometric information to a script generation module. The script generation module converts the geometric information into a syntax tree using a recurrent neural network. The script generation module scans the syntax tree with a depth-first search algorithm. The script generation module generates text data conforming to a specific programming language based on a scanning result. The text data includes a command group executable on the three-dimensional modeling software. The three-dimensional model generation unit saves the generated text data as a script for three-dimensional model generation. The three-dimensional model generation unit automatically inserts a variable definition specifying dimensions and a material into the script. By this process, the system automatically converts a complex three-dimensional shape into a script format readable and editable by a human. The system ensures data compatibility between different CAD software. The system dramatically improves reusability of design data. This technology is applicable to diverse use cases such as collaborative design using an open-source modeling tool and data provision to an automated manufacturing line.
Step 7: Output and Download of Script The script for three-dimensional model generation generated by the three-dimensional model generation unit is transmitted to the terminal via a script output unit, and the user can download the script to edit and utilize it in a design department of his/her own company, or directly transmit it to an external three-dimensional printer or a processing contractor. Specifically, the script output unit of the system encrypts the generated script for three-dimensional model generation. In this encryption process, the script output unit applies an advanced encryption standard algorithm. The script output unit packetizes the encrypted script data. The script output unit adds a destination address and an error detection code to a packet header. The script output unit transmits the packetized data to the terminal via a secure communication protocol. The terminal receives the packet data via a network interface. The terminal combines the received packet data. The terminal decrypts the combined data. The terminal saves the decrypted script data in a local storage. The terminal transfers the saved script data to an external three-dimensional printer control device. In this transfer process, the terminal triggers a process of converting geometric information in the script data into a G-code. The terminal executes slicer software in the background. The terminal outputs the generated G-code via a serial communication interface. By this process, the system realizes seamless data linkage from design data to a manufacturing apparatus. The system promotes automation of a manufacturing process while ensuring security during data transfer. This technology is applicable to fields requiring rapid data sharing, such as distributed manufacturing and an on-demand manufacturing service.
Step 8: History Management and External Data Import A history management unit centrally manages a user's input history, selection history, generated design proposals, scripts for three-dimensional model generation, download history, correction history, tendency data for each user, and the like, and when the user uploads external design data, an image, a drawing, a sketch, CAD data, three-dimensional scan data, or the like, an external data import unit analyzes these data, automatically performs redesign and optimization according to a specified application and constraint conditions, and can generate a new design proposal and a script for three-dimensional model generation. Specifically, the history management unit of the system records an operation log of the user in a time-series database. The history management unit converts the recorded operation log into a feature vector. The history management unit inputs the feature vector to a clustering algorithm. The clustering algorithm classifies a design tendency of the user. The external data import unit of the system receives the uploaded external data. The external data import unit preprocesses the received external data. For example, when three-dimensional scan data is input, the external data import unit executes a noise removal process of point cloud data. The external data import unit applies a statistical outlier removal algorithm. The external data import unit inputs the noise-removed point cloud data to a three-dimensional convolutional neural network. Input data to the three-dimensional convolutional neural network is a tensor including spatial coordinates and color information. As a specific example of the input data, a point cloud tensor having 1024 vertices can be cited. As another specific example, a voxel grid tensor having a resolution of 256 can be cited. The three-dimensional convolutional neural network extracts a local geometric feature from the input tensor. The three-dimensional convolutional neural network propagates the extracted feature to a fully connected layer. The three-dimensional convolutional neural network outputs a shape class probability and a dimensional parameter of an object. As a specific example of the output data, a score indicating a probability of 0.95 that the object is a “cylinder” can be cited. As another specific example, numerical data indicating that a radius of the object is 50 millimeters can be cited. The generative AI processing unit inputs the output shape class probability and dimensional parameter to a subsequent optimization algorithm. By this process, the system automatically restores an accurate design requirement from incomplete external data. The system streamlines reverse engineering of an existing product. This technology is applicable to diverse use cases such as CAD data restoration from an old drawing and customized part design from an actual product.

### (Specific Use Case)

For example, a case is assumed where a planner of an office supply manufacturer considers development of a new storage case used on an office desk. This planner uses the user input unit on the terminal to input “storage case used on office desk” as an application, “width 30 cm, height 10 cm, depth 15 cm” as a size, “recycled plastic” as a material, “white” as a color, and “with drawer”, “stackable”, “cost upper limit 1000 yen”, “brand logo arranged on side surface”, “anti-slip provided on bottom surface”, “assembly type”, “disassemblable and washable”, “emphasis on mass productivity”, “environmentally friendly design”, and the like as other constraint conditions. The input can be performed by diverse means such as natural language input, numerical input, option selection, image attachment, voice input, and external file import. The input data is transmitted to the server via the data transmission unit. Specifically, the user input unit of the system receives diverse input data from the planner. The user input unit integrally processes natural language text, numerical data, and image data. The user input unit performs morphological analysis on the input natural language text. The user input unit extracts a keyword from an analysis result. The user input unit maps the extracted keyword to a semantic vector space. The user input unit normalizes the input numerical data. The user input unit stores the normalized numerical data in a constraint condition matrix. The user input unit inputs the input image data to a convolutional neural network. The user input unit extracts a visual feature vector from the image data. The user input unit combines the semantic vector, the constraint condition matrix, and the visual feature vector. The user input unit generates the combined data as an integrated feature tensor. The user input unit passes the generated integrated feature tensor to the data transmission unit. The data transmission unit packetizes the integrated feature tensor. The data transmission unit transmits the packetized data to the server. By this process, the system integrates input data of different modalities into a single mathematical expression. The system dramatically improves calculation efficiency in subsequent AI processing. This technology is applicable to fields requiring advanced information integration, such as a product planning phase requiring complex requirement definition and system design where diverse constraints intersect.

The generative AI processing unit on the server analyzes the received design requirements, and automatically generates a plurality of storage case design proposals having an optimal shape, structure, material, color, and function according to the application and the constraint conditions. For example, the number and arrangement of drawers, the presence or absence of a handle, a stacking structure, a lock mechanism, the presence or absence of a partition plate, an anti-slip shape on a bottom surface, an opening/closing method of a lid, a thickness of a material, a load capacity, a cost, mass productivity, an environmental load, an arrangement of a brand logo, an assembly procedure, a disassembly procedure, and the like are automatically designed, and a plurality of design proposals optimized for the application and the constraint conditions are generated while also referring to past design data, a material property database, cost data, environmental load data, user evaluation data, trend information, and the like. Specific examples of a prompt sentence to be read by the generative AI are “Application: storage case used on office desk, Size: width 30 cm, height 10 cm, depth 15 cm, Material: recycled plastic, Color: white, Conditions: with drawer, stackable, cost upper limit 1000 yen, brand logo arranged on side surface, anti-slip provided on bottom surface, assembly type, disassemblable and washable, emphasis on mass productivity, environmentally friendly design”. Specifically, the generative AI processing unit of the system analyzes the received integrated feature tensor. The generative AI processing unit inputs the integrated feature tensor to a generator of a conditional generative adversarial network. Input data to the generator is combined data of the integrated feature tensor and a random noise vector. As a specific example of the input data, a tensor combining a 512-dimensional condition vector specifying an application and a size and a 256-dimensional Gaussian noise vector can be cited. As another specific example, a 128-dimensional constraint vector encoding a cost upper limit and material information can be cited. The generator expands the input data to a spatial dimension using a plurality of deconvolution layers. The generator outputs a material existence probability in each cell of a three-dimensional voxel grid. As a specific example of the output data, a continuous value from 0 to 1 indicating an occupation probability of each voxel in a three-dimensional grid having a resolution of 64 can be cited. As another specific example, a categorical distribution indicating a material ID assigned to each voxel can be cited. The generative AI processing unit applies a threshold process to the output material existence probability. The generative AI processing unit determines a voxel having a probability equal to or higher than a threshold as an entity. The generative AI processing unit executes a structural analysis simulation on the determined voxel group. The generative AI processing unit evaluates a load capacity and durability based on a simulation result. By this process, the system searches for a non-conventional optimal shape independent of human intuition at high speed. The system automates verification of physical constraints in an initial stage of design, and significantly reduces rework. This technology is applicable to product development requiring satisfying diverse constraints, such as automatic design of office furniture and housing design of an electronic device.

A plurality of design proposals generated by the generative AI processing unit are transmitted to the terminal via a design proposal presentation unit, and information from diverse viewpoints, such as features, an appearance image, dimensions, material information, a functional description, a cost estimate, an environmental load evaluation, a mass productivity evaluation, a user evaluation prediction, legal regulation compliance, an assembly procedure, a disassembly procedure, maintainability, customizability, part replaceability, and brand image compliance of each proposal, is presented on the terminal. For example, a three-dimensional preview image, a convenience evaluation for each application, a cost estimate, an environmental load evaluation, an assembly animation, a disassembly animation, a parts list, a material list, a processing method list, a recommended production method, a recommended distribution method, a recommended package proposal, and the like are also presented at the same time. A person in charge selects an optimal design proposal while referring to the three-dimensional preview image, the convenience evaluation for each application, the cost estimate, the environmental load evaluation, the assembly animation, the disassembly animation, the parts list, the material list, the processing method list, the recommended production method, the recommended distribution method, the recommended package proposal, and the like. Specifically, the design proposal presentation unit of the present system receives a plurality of pieces of design proposal data output from the generative AI processing unit. The design proposal data is a composite data structure including three-dimensional shape data, a cost prediction value, and an environmental load score. The design proposal presentation unit parses the received composite data structure. The design proposal presentation unit passes the three-dimensional shape data to a rendering engine. The rendering engine generates a high-definition three-dimensional preview image using a ray tracing algorithm. The design proposal presentation unit passes the cost prediction value and the environmental load score to a graph drawing module. The graph drawing module converts numerical values into visual chart data. The design proposal presentation unit generates a user interface screen in which the three-dimensional preview image and the chart data are integrated. The design proposal presentation unit outputs the generated screen data to a display of the terminal. The present system monitors a selection operation from the user. The present system holds an identifier of the selected design proposal in a memory. By this processing, the present system provides multifaceted evaluation indexes to the user in an intuitively understandable format. The present system supports a decision-making process of a designer based on quantitative data. The present technology is applicable to a situation where rapid consensus building is required, such as a product review meeting involving a plurality of stakeholders or a presentation to a customer.

An additional request or a modification instruction, such as “add one more drawer”, “change the position of the handle”, “change the material to metal”, “change the color to blue”, or “add a logo”, can also be input for the design proposal selected by the person in charge. These pieces of information are transmitted to the generative AI processing unit again, and a new design proposal reflecting modification contents is automatically generated. A specific example of a prompt sentence to be read by the generative AI is “Application: storage case used on an office desk, Size: width 30 cm, height 10 cm, depth 15 cm, Material: metal, Color: blue, Conditions: increase drawers to two tiers, change the position of the handle to the center, add a brand logo, provide an anti-slip on the bottom surface, assembly type, disassemblable and washable, emphasis on mass productivity, environmentally friendly design”. Specifically, the terminal of the present system receives the additional request and the modification instruction from the person in charge. The terminal inputs the received natural language text to a natural language processing model. The natural language processing model is a large language model based on a transformer architecture. Input data to the natural language processing model is a word embedding vector sequence. A specific example of the input data includes vector data converted from the text “increase drawers to two tiers”. Another specific example includes vector data converted from the text “change the position of the handle to the center”. The natural language processing model calculates a contextual dependency of the input vector sequence using a self-attention mechanism. The natural language processing model outputs a modification intention vector based on a calculation result. A specific example of the output data includes a vector including a structure change flag instructing the addition of a drawer. Another specific example includes a displacement vector instructing a coordinate movement of the handle. The generative AI processing unit inputs the output modification intention vector to a subsequent three-dimensional shape generation model. The three-dimensional shape generation model combines existing three-dimensional voxel data and the modification intention vector. The three-dimensional shape generation model inputs the combined data to a three-dimensional convolutional layer, and executes a local update of the shape. By this processing, the present system automatically executes an accurate three-dimensional shape change from an ambiguous natural language instruction of the user. The present system significantly reduces the time required for trial and error by the designer. The present technology is applicable to a customized design of a product or an agile development process that immediately reflects customer feedback.

Based on contents of the finally selected design proposal, the three-dimensional model generation unit on the server automatically generates a script for three-dimensional model generation usable in three-dimensional modeling software. For example, it is output in a script format of an open-source three-dimensional modeling tool (Python script, JSON format, STEP format, STL format, OBJ format, etc.), and has contents for automatically generating a three-dimensional model reflecting information such as the specified size, material, color, structure, and function. In the case of a storage case, an outer frame, a drawer, a handle, an uneven structure for stacking, a lock mechanism, a partition plate, an anti-slip on the bottom surface, an opening/closing mechanism of a lid, a label space, a divided structure for each part, an assembly procedure, a disassembly procedure, and the like are automatically arranged, and material setting reflecting dimensions and material information is also automatically performed. Specifically, the three-dimensional model generation unit of the present system acquires three-dimensional voxel data of the finally selected design proposal. The three-dimensional model generation unit converts the acquired three-dimensional voxel data into polygon mesh data. In this conversion processing, the three-dimensional model generation unit executes a marching cubes algorithm. The three-dimensional model generation unit extracts vertex coordinates and face connection information of the generated polygon mesh. The three-dimensional model generation unit inputs the extracted geometric information to a script generation module. The script generation module converts the geometric information into a syntax tree using a recursive neural network. The script generation module scans the syntax tree. The script generation module generates text data compliant with a specific programming language based on a scanning result. The text data includes a group of commands executable on the three-dimensional modeling software. The three-dimensional model generation unit saves the generated text data as the script for three-dimensional model generation. The three-dimensional model generation unit automatically inserts a material setting command into the script. The material setting command includes physically based rendering parameters such as a reflectance and a transmittance of the specified material. By this processing, the present system automatically converts a complex three-dimensional shape into a script format readable and editable by a human. The present system ensures data compatibility between different CAD software. The present system dramatically improves the reusability of design data. The present technology is applicable to diverse use cases such as collaborative design using an open-source modeling tool and data provision to an automated manufacturing line.

The script for three-dimensional model generation generated by the three-dimensional model generation unit is transmitted to the terminal via a script output unit, and the person in charge can download the script and edit/utilize it in their own design department, or directly transmit it to an external three-dimensional printer or a processing contractor. A history management unit centrally manages an input history of the person in charge, a selection history, the generated design proposals, the script for three-dimensional model generation, a download history, a modification history, tendency data for each person in charge, and the like, and when the person in charge uploads external design data, an image, a drawing, a sketch, CAD data, three-dimensional scan data, or the like, an external data import unit analyzes these data, automatically performs redesign or optimization in accordance with the specified application or constraint conditions, and can generate a new design proposal or a script for three-dimensional model generation. Specifically, the script output unit of the present system encrypts the generated script for three-dimensional model generation. In this encryption processing, the script output unit applies an advanced encryption standard algorithm. The script output unit packetizes the encrypted script data. The script output unit transmits the packetized data to the terminal via a secure communication protocol. The terminal combines the received packet data. The terminal decrypts the combined data. The terminal saves the decrypted script data in a local storage. The terminal transfers the saved script data to an external three-dimensional printer control device. In this transfer processing, the terminal triggers a process of converting geometric information in the script data into a G-code. The history management unit of the present system records an operation log of the person in charge in a time-series database. The history management unit converts the recorded operation log into a feature vector. The history management unit inputs the feature vector to a clustering algorithm. The clustering algorithm classifies a design tendency of the person in charge. The external data import unit of the present system receives the uploaded external data. The external data import unit preprocesses the received external data. The external data import unit inputs the preprocessed data to a three-dimensional convolutional neural network. The three-dimensional convolutional neural network extracts a local geometric feature from the input data. The three-dimensional convolutional neural network outputs a shape class probability and a dimensional parameter of an object. The generative AI processing unit inputs the output shape class probability and dimensional parameter to a subsequent optimization algorithm. By this processing, the present system automatically restores an accurate design requirement from incomplete external data. The present system streamlines reverse engineering of an existing product. The present technology is applicable to diverse use cases such as CAD data restoration from an old drawing and customized part design from an actual product.

(Application Example 1) The flow of the specific processing in Application Example 1 will be described. Each part of the system described below is realized by the data processing device 12 and the smart device 14. Additionally, the data processing device 12 is referred to as a “server,” and the smart device 14 is referred to as a “terminal.”

### (Embodiment for Carrying out the Present Invention)

An embodiment of the present invention will be described more specifically and in detail. The system according to the present embodiment is composed of a terminal and a server, and is configured such that the terminal provides a user interface, and the server is responsible for generative AI processing and three-dimensional model generation processing. As the terminal, any information processing apparatus capable of network connection, such as a personal computer, a tablet terminal, a smartphone, a dedicated industrial terminal, a wearable terminal, and even a touch panel terminal incorporated in a control panel in a factory, can be used. As the server, a computational resource having a calculation capability of generative AI and a three-dimensional model generation capability, such as a cloud server, an on-premises server, a distributed processing server, an edge server, or an in-factory local server, is used. Specifically, the present system adopts a client-server type distributed computing architecture. The terminal of the present system functions as an edge device that collects input data from a user. The terminal serializes the collected input data into a lightweight data format. The terminal transmits the serialized data to the server using an asynchronous communication protocol. The server distributes the received data to a plurality of calculation nodes via a load balancer. Each calculation node of the server constitutes a parallel calculation cluster using a GPU. The calculation node deploys a generative AI model on a memory. The calculation node executes inference processing on the input data in parallel. The server aggregates inference results from the respective calculation nodes. The server executes the three-dimensional model generation processing based on the aggregated result. By this processing, the present system efficiently executes the generative AI processing requiring an enormous computational resource in a distributed manner. The present system provides advanced three-dimensional model generation in real time without depending on hardware constraints on the terminal side. The present technology is applicable to a system requiring scalability, such as an edge computing environment in a factory or a globally deployed cloud-based design platform.

First, the user input unit on the terminal includes various input means such as a GUI, voice input, touch operation, pen input, import of an external file, and automatic acquisition of on-site information by a barcode reader or an RFID reader. The user can simultaneously specify a plurality of extremely diverse and complex conditions, such as a shape of an object to be conveyed (e.g., rectangular parallelepiped, cylinder, sphere, irregularly shaped object, bag shape, plate shape, complex curved surface shape, flexible object, liquid container, powder bag, etc.), dimensions (e.g., width 40 cm×depth 30 cm×height 20 cm, diameter 7 cm x height 25 cm, plate shape with a thickness of 2 mm, maximum external dimensions within 100 mm, etc.), weight (e.g., 5 kilograms, 100 grams, 20 kilograms, maximum 30 kilograms, minimum 10 grams, etc.), size/constraints of a work space (e.g., width 1 meter×depth 1 meter×height 1.5 meters, ceiling height limit 1.2 meters, presence/absence of an obstacle, movable range limit, interference avoidance with adjacent equipment, cooperative operation area with a worker, height limit of a conveyance line, etc.), a gripping method (e.g., suction pad, gripper, magnetic force, vacuum, clamp, tweezers, hook, belt, vacuum, adhesive pad, air blow, electrostatic suction, flexible finger gripper, multi-finger robot hand, soft gripper for a collaborative robot, etc.), a desired material (e.g., aluminum, resin, stainless steel, carbon, rubber, food hygiene compliant material, heat-resistant material, chemical-resistant material, antistatic material, antibacterial material, lightweight composite material, resin for 3D printing, etc.), a necessary special function (e.g., heating, cooling, weight sensor, image sensor, force sensor, static electricity removal, antibacterial coating, wear detection, self-diagnosis function, IoT communication function, QR reader for workpiece identification, workpiece automatic recognition AI, abnormality detection AI, remote monitoring function, self-position correction function, automatic part replacement function, cleaning automation function, etc.), a cost upper limit (e.g., 100,000 yen, 300,000 yen, 1,000,000 yen, cost per unit, cost during mass production, unit price of a part, maintenance cost, etc.), durability (e.g., 100,000 cycles, 1,000,000 cycles, impact resistance, wear resistance, corrosion resistance, chemical resistance, heat resistance, low-temperature resistance, long-term oil-free, maintenance-free, part replacement cycle, MTBF, etc.), hygiene requirements (e.g., food factory compliance, medical site compliance, emphasis on cleanability, foreign matter mixing prevention, aseptic compliance, cleaning liquid resistance, autoclave compliance, disassemblable and washable, antibacterial coating, foreign matter detection sensor mounting, etc.), an installation space (e.g., maximum installable external dimensions, interference avoidance with peripheral equipment, compatibility with existing equipment, portable design, ease of relocation, etc.), an operation speed (e.g., conveyance time per cycle, maximum acceleration, maximum speed, acceleration/deceleration control, impact mitigation mechanism, synchronous control with a conveyance line, etc.), mass productivity (e.g., standardization of parts, reduction in assembly man-hours, reduction in the number of parts, modular design, 3D printer compliance, ease of on-site assembly, etc.), maintainability (e.g., ease of disassembly, part replaceability, life prediction of a consumable part, remote diagnosis function, self-diagnosis function, maintenance history management, etc.), presence/absence of a replacement part (e.g., consumable list, replacement cycle, availability of on-site replacement, replacement work procedure, standardization of replacement parts, etc.), on-site safety standards (e.g., collaborative robot standard, ISO standard compliance, fail-safe design, emergency stop function, safety cover, photoelectric sensor interlocking, worker detection function, automatic stop at the time of abnormality, etc.), legal regulation compliance (e.g., Electrical Safety Law, Food Sanitation Law, medical device regulation, CE marking, RoHS directive, safety standards of each country, etc.), a brand image (e.g., engraving of a corporate logo, adoption of a brand color, design guideline compliance, design right compliance, etc.), and further, special requirements specific to the site (e.g., explosion-proof compliance, dust-proof and drip-proof, ultraviolet resistance, radiation resistance, chemical resistance, oil resistance, salt damage resistance, weather resistance, low-noise design, static electricity countermeasure, antistatic, environmentally friendly design, recycling compliance, carbon-neutral design, etc.). Specifically, the user input unit of the present system integrally processes signals from diverse input devices. The user input unit converts a capacitance change from a touch panel into two-dimensional coordinate data. The user input unit samples an analog acoustic signal from a voice input microphone into digital waveform data. The user input unit converts the digital waveform data into frequency spectrum data by fast Fourier transform. The user input unit inputs the frequency spectrum data to an acoustic model and decodes it into text data. The user input unit converts an optical reflection signal from the barcode reader into a digital code. The user input unit normalizes these diverse input data. The user input unit maps the normalized data to a multidimensional constraint condition vector. The constraint condition vector holds each item such as the shape, dimensions, and weight of the object to be conveyed, the constraints of the work space, the gripping method, the desired material, the special function, the cost upper limit, the durability, and the hygiene requirements as an independent dimension. The user input unit transmits the generated constraint condition vector to the server. By this processing, the present system integrates complex and diverse requirements of the site into a single mathematical expression processable by a computer. The present system absorbs a difference in input modality and enhances the versatility of subsequent AI processing. The present technology is applicable to an engineering task requiring simultaneous consideration of extremely diverse parameters, such as requirement definition of a robot hand at a manufacturing site or specification formulation of automated equipment.

For example, detailed requirements differing for each site can be flexibly specified, such as when the user inputs “Object: rectangular parallelepiped cardboard box, Dimensions: 40 cm×30 cm×20 cm, Weight: 5 kilograms, Work space: width 1 meter×depth 1 meter×height 1.5 meters, Gripping method: suction pad, Material: aluminum, Special function: built-in weight sensor, Cost upper limit: 100,000 yen, Durability: 100,000 cycles or more, Hygiene requirements: food factory compliance, Installation space: maximum external dimensions within 1.2 meters, Operation speed: within 3 seconds per cycle, Mass productivity: standardization of parts, Maintainability: disassemblable and washable, Replacement part: suction pad replaceable, On-site safety standards: collaborative robot standard compliance, Legal regulations: Food Sanitation Law compliance, Brand image: corporate logo engraving”, when the user inputs “Object: cylindrical PET bottle, Dimensions: diameter 7 cm×height 25 cm, Weight: 500 grams, Work space: width 80 cm×depth 80 cm×height 1.2 meters, Gripping method: gripper, Material: resin, Special function: image sensor mounting, Cost upper limit: 50,000 yen, Durability: 500,000 cycles, Hygiene requirements: emphasis on cleanability, Installation space: maximum external dimensions within 1 meter, Operation speed: within 2 seconds per cycle, Mass productivity: 3D printer compliance, Maintainability: easy part replacement, Replacement part: fingertip pad replaceable, On-site safety standards: ISO standard compliance, Legal regulations: CE marking, Brand image: adoption of brand color”, or when the user inputs “Object: irregularly shaped food pack, Dimensions: maximum 30 cm×20 cm×10 cm, Weight: 1 kilogram, Work space: width 1.5 meters x depth 1 meter×height 1 meter, Gripping method: vacuum suction, Material: stainless steel, Special function: antibacterial coating, Cost upper limit: 200,000 yen, Durability: 200,000 cycles, Hygiene requirements: aseptic compliance, Installation space: maximum external dimensions within 1.5 meters, Operation speed: within 4 seconds per cycle, Mass productivity: modular design, Maintainability: easy disassembly and cleaning, Replacement part: vacuum pad replaceable, On-site safety standards: fail-safe design, Legal regulations: RoHS directive, Brand image: design right compliance”. Specifically, the user input unit of the present system inputs the input detailed requirement text to a natural language processing model. The natural language processing model is a large language model based on a transformer architecture. Input data to the natural language processing model is a word embedding vector sequence. A specific example of the input data includes vector data converted from the text “Object: rectangular parallelepiped cardboard box, Dimensions: 40 cm×30 cm×20 cm”. Another specific example includes vector data converted from the text “Gripping method: suction pad, Material: aluminum, Special function: built-in weight sensor”. The natural language processing model calculates a contextual dependency of the input vector sequence using a self-attention mechanism. The natural language processing model outputs a requirement extraction vector based on a calculation result. The requirement extraction vector is expressed as, for example, a coordinate value on a 2048-dimensional latent space. A specific example of the output data includes a vector including a categorical variable specifying the suction pad method. Another specific example includes a vector including numerical data indicating a spatial constraint of maximum external dimensions within 1.2 meters. The user input unit converts the output requirement extraction vector into a structured data format. The user input unit transmits the structured data to the server. By this processing, the present system accurately extracts parameters necessary for design from unstructured text. The present system absorbs human input fluctuation and realizes consistent definition of design requirements. The present technology is applicable to a system that automatically converts diverse requests from a customer into a specification document, an equipment adjustment system based on an oral instruction of an on-site worker, and the like.

The terminal transmits these input data to the server. A generative AI processing unit is provided on the server side, where a generative AI analyzes the input design requirements. The generative AI makes a comprehensive judgment by linking a plurality of AI modules such as natural language processing, image recognition, structural optimization, material property inference, past design database reference, user history analysis, similar case search, trend analysis, cost simulation, durability evaluation, hygiene evaluation, legal regulation compliance evaluation, on-site feedback learning, on-site accident data analysis, equipment operation data analysis, part life prediction AI, abnormality detection AI, on-site work video analysis AI, and on-site voice analysis AI. For example, when the suction pad method is specified, a surface state and weight of the object, a conveyance speed, constraints of the work space, hygiene requirements, on-site temperature and humidity conditions, an on-site dust/oil/moisture environment, a wear/deterioration/replacement history of the suction pad, a power consumption/noise/maintenance history of a vacuum generation mechanism, chemical resistance/heat resistance/wear resistance of a pad material, pad replaceability, pad cleanability, a pad wear detection function, a vacuum leak detection function, an optimal layout of vacuum piping, selection of a vacuum generation source, a vacuum pressure control algorithm, an automatic adjustment function of suction force, a recovery operation at the time of suction failure, an automatic cleaning mechanism of the suction pad, an automatic replacement mechanism of the suction pad, inventory management linkage of the suction pad, and the like are automatically designed. In the case of the gripper method, the number of fingers, a movable range of the fingers, a fingertip shape, an anti-slip material, the presence/absence of a force sensor, finger replaceability, grip force, an opening/closing speed, a foreign matter mixing prevention structure, cleanability, durability, cost, fingertip pad wear detection, an automatic replacement mechanism of the fingertip pad, an automatic alignment mechanism of the gripper, a self-diagnosis function of the gripper, a remote monitoring function of the gripper, an automatic stop function at the time of abnormality of the gripper, an on-site worker detection interlocking function of the gripper, on-site safety standard compliance of the gripper, and the like are automatically optimized. In the case of the magnetic force method, the type of magnet, magnetic force strength, an attachment/detachment mechanism, material compatibility of the object, a magnetic shield, malfunction prevention, cost, durability, hygiene, an automatic attachment/detachment mechanism of the magnet, wear detection of the magnet, temperature rise detection of the magnet, an automatic stop function at the time of abnormality of the magnet, and the like are automatically designed. Specifically, the generative AI processing unit of the present system analyzes the received design requirement data. The generative AI processing unit inputs the design requirement data to a multilayer perceptron. Input data to the multilayer perceptron is a multidimensional feature vector in which the design requirements are encoded. A specific example of the input data includes a numerical vector obtained by normalizing the weight and dimensions of the object and the required number of durability cycles. Another specific example includes a vector obtained by one-hot encoding a categorical variable of the specified gripping method or material. The multilayer perceptron non-linearly transforms the input vector. The multilayer perceptron outputs an optimal value of each design parameter. A specific example of the output data includes two-dimensional array data indicating optimal arrangement coordinates of the suction pads. Another specific example includes a continuous value score indicating a necessary suction force of the vacuum generation mechanism. The generative AI processing unit generates an initial model of a three-dimensional shape based on the output optimal value. The generative AI processing unit executes a structural analysis simulation based on a finite element method on the initial model. The generative AI processing unit evaluates a simulation result as a reward function of a reinforcement learning agent. The reinforcement learning agent iteratively updates a shape parameter so as to maximize a reward. By this processing, the present system autonomously searches for an unconventional optimal design that does not depend on human rules of thumb. The present system derives a design proposal satisfying complex physical constraints at high speed. The present technology is applicable to a field requiring advanced engineering knowledge, such as automatic design of a robot end effector and part design of an industrial machine operating under a special environment.

The generative AI generates a plurality of design proposals optimized for the application and the constraint conditions while also referring to past design data, design patterns, a material property database, a user's input history, industry standards, legal regulations, cost data, durability data, hygiene data, user evaluation data, trend information, on-site feedback, on-site accident data, equipment operation data, part life prediction data, abnormality detection data, on-site work video data, on-site voice data, and the like. For example, variations according to diverse requests of the site are automatically generated, such as a proposal in which four suction pads are arranged, a proposal in which six suction pads are arranged, a proposal in which an arm is made telescopic, a proposal in which a joint portion is made of resin to reduce weight, a proposal in which a sensor is built in a gripper tip, a proposal in which an antibacterial coating is applied, a proposal in which a self-diagnosis function is mounted, a proposal in which an IoT communication function is provided, a proposal having a disassembled structure emphasizing cleanability, a proposal having a reinforcing structure for enhancing durability, a proposal frequently using standard parts to suppress cost, a fail-safe design proposal compliant with on-site safety standards, a collaborative robot compliant proposal considering cooperative operation with an on-site worker, a dust-proof and drip-proof/chemical-resistant/heat-resistant/cold-resistant/ultraviolet-resistant/radiation-resistant/low-noise design proposal according to an on-site work environment, a design proposal matching an on-site brand image, and a design proposal compliant with on-site legal regulations. Specifically, the generative AI of the present system inputs the past design data and the on-site feedback data to a graph neural network. Input data to the graph neural network is graph structure data including an adjacency matrix representing a connection relationship between parts and an attribute vector of each part. A specific example of the input data includes a list of nodes and edges indicating a connection relationship between the suction pad and the arm. Another specific example includes an attribute value tensor such as a material, weight, and cost assigned to each node. The graph neural network propagates features between nodes using a message passing algorithm. The graph neural network outputs a latent representation vector of the entire graph. A specific example of the output data includes numerical data indicating a durability score of the entire design proposal. Another specific example includes a score indicating a probability that a specific part configuration satisfies the on-site safety standards. The generative AI inputs the output latent representation vector to a decoder of a conditional variational autoencoder. The decoder generates a plurality of diverse design variations from the latent representation vector. The generative AI executes constraint satisfaction determination for each generated variation. The generative AI filters only design proposals satisfying the constraints. By this processing, the present system integrates an enormous amount of past knowledge as a mathematical model and applies it to a new design. The present system presents not only a single optimal solution but also a plurality of alternatives having diverse trade-offs. The present technology is applicable to automatic selection of an alternative part according to a fluctuation in a supply chain, automatic generation of a derivative model suitable for a different on-site environment, and the like.

The plurality of design proposals generated by the generative AI processing unit on the server are transmitted to the terminal. On the terminal, information from extremely diverse viewpoints, such as features, an appearance image, dimensions, material information, a functional description, a cost estimate, a durability evaluation, a hygiene evaluation, a mass productivity evaluation, a user evaluation prediction, legal regulation compliance, an assembly procedure, a disassembly procedure, maintainability, customizability, part replaceability, brand image compliance, on-site safety standard compliance, cooperativeness with an on-site worker, compatibility with on-site equipment, suitability for an on-site work environment, suitability for an on-site maintenance system, suitability for an on-site education system, on-site IoT linkage, on-site data linkage, and on-site DX promotion of each proposal, is presented. For example, a three-dimensional preview image, a convenience evaluation for each application, a cost estimate, a durability evaluation, a hygiene evaluation, an assembly animation, a disassembly animation, a parts list, a material list, a processing method list, a recommended production method, a recommended distribution method, a recommended package proposal, an on-site work video simulation, a cooperative operation simulation with an on-site worker, an interference check simulation with on-site equipment, an on-site IoT linkage simulation, an on-site maintenance work simulation, and the like are also presented at the same time. The user can select an optimal design proposal while referring to these pieces of information. Specifically, the design proposal presentation unit of the present system receives a plurality of pieces of design proposal data output from the generative AI processing unit. The design proposal data is a composite data structure including three-dimensional shape data, a cost prediction value, a durability evaluation score, and on-site work video simulation data. The design proposal presentation unit parses the received composite data structure. The design proposal presentation unit passes the three-dimensional shape data to a rendering engine. The rendering engine generates a high-definition three-dimensional preview image using a ray tracing algorithm. The design proposal presentation unit passes the on-site work video simulation data to a physics engine. The physics engine calculates an operation trajectory of a robot using rigid body dynamics and a collision determination algorithm. The design proposal presentation unit generates animation data based on a calculation result. The design proposal presentation unit generates a user interface screen in which the three-dimensional preview image, the animation data, and various evaluation scores are integrated. The design proposal presentation unit outputs the generated screen data to a display of the terminal. The present system monitors a selection operation from the user. The present system holds an identifier of the selected design proposal in a memory. By this processing, the present system provides multifaceted evaluation indexes and dynamic simulation results to the user in an intuitively understandable format. The present system supports a decision-making process of a designer based on quantitative data and visual verification. The present technology is applicable to an engineering task in which confirmation of dynamic behavior is indispensable, such as pre-introduction verification of a robot system or layout examination of a production line.

When a user selects a design proposal, a terminal transmits the selection information to a server, and a three-dimensional model generation unit on the server automatically generates a script for three-dimensional model generation usable in three-dimensional modeling software based on contents of the selected design proposal. This script for three-dimensional model generation is output, for example, in a script format of an open-source three-dimensional modeling tool (such as a Python script, a STEP format, an STL format, an OBJ format, a 3MF format, an IGES format, a VRML format, and an FBX format), and has contents for automatically generating a three-dimensional model reflecting information such as a specified shape, dimensions, material, structure, function, special function, durability, hygiene requirements, on-site safety standards, on-site IoT connectivity, and on-site DX promotion capability. For example, an arm with a suction pad, a joint portion, a sensor-embedded part, a reinforcing structure, a disassemblable and washable structure, an antibacterial coating portion, an IoT communication module, a self-diagnosis function portion, an on-site worker detection sensor portion, an on-site IoT linkage interface portion, an on-site maintenance work support portion, and the like are automatically arranged, and material settings reflecting dimensions and material information are also automatically performed. Furthermore, the script for three-dimensional model generation can also incorporate a parameter setting function that allows the user to make fine adjustments later (for example, dimensions, material, presence/absence of parts, function addition/deletion, IoT linkage setting, on-site worker detection setting, on-site maintenance work support setting, on-site DX promotion setting, and the like), an automatic generation function of a plurality of variations, an application-specific durability analysis and cost estimation function, a hygiene evaluation function, an assembly/disassembly animation generation function, a parts list/material list automatic generation function, a processing method recommendation function, a mass productivity evaluation function, a user evaluation prediction function, a legal regulation compliance check function, an on-site IoT connectivity evaluation function, an on-site DX promotion capability evaluation function, and the like. Specifically, the three-dimensional model generation unit of the present system acquires three-dimensional voxel data of the selected design proposal. The three-dimensional model generation unit converts the acquired three-dimensional voxel data into polygon mesh data. In this conversion process, the three-dimensional model generation unit executes a marching cubes algorithm. The three-dimensional model generation unit extracts vertex coordinates and face connection information of the generated polygon mesh. The three-dimensional model generation unit inputs the extracted geometric information to a script generation module. The script generation module converts the geometric information into a syntax tree using a recursive neural network. The script generation module traverses the syntax tree. The script generation module generates text data compliant with a specific programming language based on a traversal result. The text data includes a group of commands executable on the three-dimensional modeling software. The three-dimensional model generation unit saves the generated text data as the script for three-dimensional model generation. The three-dimensional model generation unit automatically inserts a parameterized variable definition into the script. The variable definition provides an interface for the user to change dimensions and materials later. By this process, the present system automatically converts a complex three-dimensional shape into a human-readable and editable parametric script format. The present system ensures data compatibility between different CAD software. The present system dramatically improves reusability and customizability of design data. The present technology is applicable to various use cases such as collaborative design using an open-source modeling tool and data provision to an automated manufacturing line.

In addition, even when the user performs input a plurality of times with different applications and conditions, the generative AI can learn past input histories, selection tendencies, on-site feedback, on-site accident data, equipment operation data, part life prediction data, abnormality detection data, on-site work video data, on-site audio data, and the like, and can automatically generate proposals and design proposals optimized for each user. For example, for a user who has designed a “suction pad method” a plurality of times in the past, it is possible to learn a preferred pad arrangement, material, cost range, brand image, on-site IoT connectivity, on-site DX promotion capability, and the like, and automatically make a more personalized proposal. Furthermore, even when the user inputs an additional request or a modification instruction (for example, “increase the number of suction pads”, “extend the length of the arm”, “change the material to stainless steel”, “add a sensor”, “add an IoT linkage function”, “add an on-site worker detection function”, “add an on-site maintenance work support function”, “add an on-site DX promotion function”, and the like) for the design proposal selected by the user, the generative AI can immediately analyze the contents and automatically regenerate a new design proposal and a script for three-dimensional model generation reflecting the modified contents. Specifically, the generative AI of the present system inputs the user's past input history and selection tendency to a recurrent neural network. Input data to the recurrent neural network is an embedding vector sequence of operation logs arranged in chronological order. A specific example of the input data includes sequence data of selected material IDs in the past five design sessions. Another specific example includes a feature vector sequence of a natural language text input as an additional request. The recurrent neural network learns a long-term dependency of time-series data using long short-term memory cells. The recurrent neural network outputs a latent preference vector of the user. A specific example of the output data includes a weighting coefficient vector indicating a tendency to emphasize durability over cost. Another specific example includes a probability distribution of preferring a specific brand color. The generative AI uses the output preference vector as a condition vector when generating a next design proposal. When receiving an additional request from the user, the generative AI immediately extracts a modification intention vector using a natural language processing model. The generative AI combines the modification intention vector and existing design data, and inputs them to a three-dimensional shape generation model. The three-dimensional shape generation model executes a local update of a shape based on the combined data. By this process, the present system continuously learns an individual design style of the user and improves personalized proposal accuracy. The present system actualizes latent needs of the user through an interactive design process. The present technology is applicable to an expert system that learns know-how of a skilled designer and a recommendation system that proposes a product optimized for each customer.

Furthermore, even when the user uploads external design data, an image, a drawing, a sketch, CAD data, three-dimensional scan data, on-site work video data, on-site audio data, on-site IoT data, on-site DX data, and the like, the generative AI can analyze these data, comprehensively consider a specified application and constraint conditions, on-site feedback, on-site accident data, equipment operation data, part life prediction data, abnormality detection data, on-site work video data, on-site audio data, on-site IoT data, on-site DX data, and the like, automatically perform redesign and optimization in accordance with the specified application and constraint conditions, and generate a new design proposal and a script for three-dimensional model generation. For example, by uploading three-dimensional scan data of an existing end effector and giving instructions such as “add a suction pad based on this shape”, “change the material”, “enlarge the dimensions”, “make it compatible with a specific part”, “add an IoT linkage function”, “add an on-site worker detection function”, “add an on-site maintenance work support function”, and “add an on-site DX promotion function”, the generative AI can automatically perform an optimized design and output a script for three-dimensional model generation. Specifically, an external data import unit of the present system receives the uploaded external data. The external data import unit preprocesses the received external data. For example, when three-dimensional scan data is input, the external data import unit executes a noise removal process on point cloud data. The external data import unit inputs the noise-removed point cloud data to a three-dimensional convolutional neural network. Input data to the three-dimensional convolutional neural network is a tensor including spatial coordinates and color information. A specific example of the input data includes a point cloud tensor having 1024 vertices. Another specific example includes a voxel grid tensor with a resolution of 256. The three-dimensional convolutional neural network extracts a local geometric feature from the input tensor. The three-dimensional convolutional neural network propagates the extracted feature to a fully connected layer. The three-dimensional convolutional neural network outputs a shape class probability and a dimensional parameter of an object. A specific example of the output data includes a score indicating a probability of 0.95 that the object is an “existing end effector”. Another specific example includes numerical data indicating that a flange diameter of the object is 50 millimeters. The generative AI processing unit inputs the output shape class probability and dimensional parameter to a subsequent optimization algorithm. The generative AI processing unit combines the extracted geometric feature and an additional instruction vector from the user. The generative AI processing unit inputs the combined data to a conditional generative model, and generates a new design proposal. By this process, the present system automatically restores an accurate design requirement from incomplete external data and integrates it with a new requirement. The present system seamlessly combines reverse engineering and customized design of an existing product. The present technology is applicable to various use cases such as a retrofit design of old equipment and an automatic design of an interface-compatible part with a product of another company.

As described above, in the embodiment of the present invention, by adopting a configuration in which the user input unit is realized by the terminal, and the generative AI processing unit and the three-dimensional model generation unit are realized by the server, it is possible to reduce a calculation load on the terminal side and realize advanced design proposal generation and three-dimensional model generation processing utilizing a high-performance generative AI on the server side. The terminal can be composed of a personal computer, a tablet terminal, a smartphone, an industrial dedicated terminal, a wearable terminal, an in-factory control panel embedded terminal, and the like, and the server can be composed of a cloud server, an on-premises server, a distributed processing server, an edge server, an in-factory local server, and the like. Specifically, the present system adopts a client-server type distributed computing architecture. This architecture eliminates constraints on computing resources on the terminal side. The present system arranges an artificial intelligence model holding a huge number of parameters, such as a large language model and a three-dimensional convolutional neural network, on a parallel computing cluster using an image processing apparatus on the server side. By this arrangement, the present system significantly shortens a calculation time required for inference processing. The present system executes a lightweight web browser or a dedicated application on the terminal side. The terminal serializes input data from the user and transmits it to the server. The server converts the received data into a tensor format. The server inputs the converted tensor data to the artificial intelligence model. The artificial intelligence model executes an optimization calculation in a feature space of hundreds of millions of dimensions. By this calculation, the present system generates a vertex coordinate group and face polygon data of a highly accurate three-dimensional model. The present system encodes the generated data into a lightweight intermediate representation format. The server returns the encoded data to the terminal. The terminal renders the received data on a screen using graphics processing hardware. By this series of processing, the present system suppresses battery consumption and heat generation of the terminal. At the same time, the present system maximizes the use of scalable computing resources on the server side. As a technical effect, the present system enables an advanced artificial intelligence-driven design task even from a mobile environment or a powerless control terminal in a factory. As a specific application field of the present system, the present system is used for an impromptu jig design at a production line start-up site or a maintenance and inspection site in the manufacturing industry.

As described above, according to the embodiment of the present invention, by combining advanced automatic design and automatic three-dimensional model generation processing on the server side with the generative AI as a core and an intuitive user interface on the terminal side, it is possible to significantly improve the efficiency of an initial design and a prototyping process in designing and prototyping an arm and an end effector of a conventional factory robot, and to realize a system capable of easily and quickly automatically generating various three-dimensional models even by a user having no specialized knowledge. Specifically, the present system includes an interface layer that converts a human intuitive operation input into machine-readable high-dimensional vector data. The interface layer encodes a natural language text or a two-dimensional sketch image input by the user into a feature vector using a natural language processing model and an image recognition model. The present system transfers the encoded feature vector to a generative artificial intelligence model on the server side. The generative artificial intelligence model includes a self-attention mechanism based on a transformer architecture. The self-attention mechanism calculates a dependency relationship between respective elements of the input feature vector. By this calculation, the model maps physical constraint conditions such as a joint angle of the robot arm and a gripping force of the end effector in a latent space. The model decodes three-dimensional voxel data or point cloud data from the mapped latent representation. In this decoding process, the model functions as a generator of a generative adversarial network. The present system inputs the generated three-dimensional data to a physical simulation engine. The engine automatically executes a stress distribution and an interference check of the generated shape. The present system feeds back a simulation result as a reward signal to a reinforcement learning algorithm. By this feedback loop, the present system autonomously improves physical validity of the design proposal. As a technical effect, the present system shortens a trial-and-error process that required several days for a human designer to a computer processing of several seconds to several minutes. The present system eliminates personalization of design and ensures quality of a certain level or higher. As a specific application field of the present system, the present system is applied to a rapid setup change of a robot hand and on-demand manufacturing of a custom-made part in a smart factory that performs high-mix low-volume production.

### (System Configuration)

The system according to the present embodiment includes a user input unit, a data transmission unit, a generative AI processing unit, a design proposal presentation unit, a user selection unit, a three-dimensional model generation unit, a script output unit, a history management unit, and an external data import unit. The user input unit has a function for the user to input information necessary for designing an arm or an end effector of a factory robot on the terminal, and can specify, for example, a rectangular parallelepiped, a cylinder, a sphere, an irregularly shaped object, a bag shape, a plate shape, a flexible object, a liquid container, a powder bag, and the like as a shape of an object to be conveyed, can input a width of 40 cm×a depth of 30 cm×a height of 20 cm, a diameter of 7 cm×a height of 25 cm, a plate shape with a thickness of 2 mm, a maximum external dimension within 100 mm, and the like as dimensions, and can specify 5 kilograms, 100 grams, 20 kilograms, a maximum of 30 kilograms, a minimum of 10 grams, and the like as a weight. As a size and constraints of a work space, a width of 1 meter×a depth of 1 meter×a height of 1.5 meters, a ceiling height limit, presence/absence of an obstacle, a movable range limit, interference avoidance with adjacent equipment, a cooperative operation area with a worker, a height limit of a conveyance line, and the like can be input, and as a gripping method, a suction pad, a gripper, a magnetic force, a vacuum, a clamp, tweezers, a hook, a belt, a vacuum, an adhesive pad, an air blow, electrostatic adsorption, a flexible finger gripper, a multi-fingered robot hand, a soft gripper for a collaborative robot, and the like can be selected. As a desired material, aluminum, resin, stainless steel, carbon, rubber, a food hygiene compliant material, a heat-resistant material, a chemical-resistant material, an antistatic material, an antibacterial material, a lightweight composite material, a resin for 3D printing, and the like can be specified, and as a necessary special function, heating, cooling, a weight sensor, an image sensor, a force sensor, static electricity removal, an antibacterial coating, wear detection, a self-diagnosis function, an IoT communication function, a QR reader for workpiece identification, a workpiece automatic recognition AI, an abnormality detection AI, a remote monitoring function, a self-position correction function, an automatic part replacement function, an automated washing function, and the like can be input. As a cost upper limit, 100,000 yen, 300,000 yen, 1,000,000 yen, a cost per unit, a cost during mass production, a unit price of a part, a maintenance cost, and the like can be specified, and as durability, 100,000 cycles, 1,000,000 cycles, impact resistance, wear resistance, corrosion resistance, chemical resistance, heat resistance, low-temperature resistance, long-term oil-free, maintenance-free, a part replacement cycle, MTBF, and the like can be input. As hygiene requirements, food factory compliance, medical site compliance, emphasis on washability, foreign matter contamination prevention, aseptic compliance, cleaning liquid resistance, autoclave compliance, disassemblable and washable, an antibacterial coating, mounting of a foreign matter detection sensor, and the like can be specified, and an installation space, an operation speed, mass productivity, maintainability, presence/absence of a replacement part, on-site safety standards, legal regulation compliance, a brand image, on-site specific special requirements, and the like can also be input simultaneously in plurality. Specifically, the user input unit temporarily stores the input multidimensional parameter group as a structured data object on a memory. The present system executes preprocessing for inputting each input parameter to an embedding layer of a natural language processing model. In this preprocessing, the present system normalizes dimensions and weight, which are numerical data, and converts them into a continuous value vector. The present system converts a shape and a material, which are categorical data, into one-hot encoding or a learned word embedding vector. The present system combines these heterogeneous vectors to generate a single high-dimensional input tensor. For example, the present system expresses numerical values of a width of 40 cm, a depth of 30 cm, a height of 20 cm, and a weight of 5 kilograms as a four-dimensional floating-point array. The present system expresses a category of a suction pad as a 512-dimensional dense vector. The present system combines these and uses them as input data to the artificial intelligence model. The present system automatically complements a missing value of the input data using mean value imputation or a prediction model. The present system detects a logical contradiction between the input constraint conditions in advance using a rule-based inference engine. For example, the present system generates a warning flag when a low cost upper limit is set while specifying a heat-resistant material. As a technical effect, the present system guarantees quality of input data to a subsequent artificial intelligence model. The present system improves inference accuracy of the artificial intelligence model and prevents generation of an invalid design proposal in advance. As a specific application field of the present system, the present system is used as a support tool for a sales representative or an on-site engineer to input requirements into the system without omission in a requirement definition phase of automated equipment in which complex requirements are intertwined.

The data transmission unit plays a role of transmitting all information input by the user input unit to the server, and also performs encryption of network communication, data format conversion, retransmission control at the time of a transmission error, consistency check of input data, automatic data collection from an on-site terminal, automatic transmission of on-site information by a barcode or RFID, real-time transmission of on-site IoT data, upload transmission of on-site work video and audio data, and the like. Specifically, the data transmission unit controls a communication module of the terminal and establishes a secure transport layer protocol. The data transmission unit packetizes the input structured data and multimedia data. The data transmission unit encrypts the packetized data using a public key cryptography method. The data transmission unit aggregates time-series temperature data and vibration data acquired from a sensor group on site for each certain time window. The data transmission unit formats the aggregated time-series data into a tensor format that can be input to a one-dimensional convolutional neural network. The data transmission unit executes a downsampling process of sampling a frame group of an on-site work video and reducing a resolution. The data transmission unit streaming-transmits the downsampled image tensor to the server. The data transmission unit constantly monitors a bandwidth of a network. The data transmission unit executes adaptive bitrate control to dynamically increase a compression rate of transmission data when the bandwidth decreases. The data transmission unit calculates a hash value of a transmission packet and enables data integrity verification on the server side. As a technical effect, the present system reliably and safely reaches a large capacity of design requirement data and on-site context data to the server without loss even under an unstable wireless communication environment in a factory. As a specific application field of the present system, the present system is used in an edge computing environment that feeds back an on-site situation in real time from a manufacturing site with much radio wave interference or a remote plant to an artificial intelligence server on a cloud.

The generative AI processing unit operates on the server, analyzes the design requirements transmitted from the user, and makes a comprehensive judgment by linking a plurality of AI modules such as natural language processing, image recognition, structural optimization, material property inference, past design database reference, user history analysis, similar case search, trend analysis, cost simulation, durability evaluation, hygiene evaluation, legal regulation compliance evaluation, on-site feedback learning, on-site accident data analysis, equipment operation data analysis, part life prediction AI, abnormality detection AI, on-site work video analysis AI, and on-site audio analysis AI. For example, when a suction pad method is specified, a surface state and weight of an object, a conveyance speed, constraints of a work space, hygiene requirements, on-site temperature and humidity conditions, an on-site dust/oil/moisture environment, a wear/deterioration/replacement history of a suction pad, power consumption/noise/maintenance history of a vacuum generation mechanism, chemical resistance/heat resistance/wear resistance of a pad material, pad replaceability, pad washability, a pad wear detection function, a vacuum leak detection function, an optimal layout of vacuum piping, selection of a vacuum generation source, a vacuum pressure control algorithm, an automatic adjustment function of a suction force, a recovery operation at the time of suction failure, an automatic cleaning mechanism of a suction pad, an automatic replacement mechanism of a suction pad, inventory management linkage of a suction pad, and the like are automatically designed. In the case of a gripper method, the number of fingers, a movable range of a finger, a fingertip shape, an anti-slip material, presence/absence of a force sensor, finger replaceability, a grip force, an opening/closing speed, a foreign matter contamination prevention structure, washability, durability, cost, wear detection of a fingertip pad, an automatic replacement mechanism of a fingertip pad, an automatic alignment mechanism of a gripper, a self-diagnosis function of a gripper, a remote monitoring function of a gripper, an automatic stop function at the time of abnormality of a gripper, an on-site worker detection interlocking function of a gripper, on-site safety standard compliance of a gripper, and the like are automatically optimized. In the case of a magnetic force method, a type of magnet, magnetic force strength, an attachment/detachment mechanism, material compatibility of an object, a magnetic shield, malfunction prevention, cost, durability, hygiene, an automatic attachment/detachment mechanism of a magnet, wear detection of a magnet, temperature rise detection of a magnet, an automatic stop function at the time of abnormality of a magnet, and the like are automatically designed. Specific examples of a prompt sentence to be read by the generative AI include “Object: rectangular cardboard box, dimensions 40 cm×30 cm×20 cm, weight 5 kilograms, work space: width 1 meter×depth 1 meter×height 1.5 meters, gripping method: suction pad, material: aluminum, special function: built-in weight sensor, cost upper limit: 100,000 yen, durability: 100,000 cycles or more, hygiene requirements: food factory compliant, installation space: maximum external dimensions within 1.2 meters, operation speed: 1 cycle within 3 seconds, mass productivity: part standardization, maintainability: disassemblable and washable, replacement part: suction pad replaceable, on-site safety standards: collaborative robot standard compliant, legal regulations: Food Sanitation Act compliant, brand image: corporate logo engraved”, and the like. Specifically, the generative AI processing unit adopts an ensemble learning architecture integrating a plurality of specialized neural network models. The processing unit divides the input prompt sentence into a token sequence using a tokenizer of a large language model. The processing unit converts the token sequence into a multidimensional word embedding vector. The processing unit inputs the converted vector to a transformer-based encoder. The encoder extracts a contextual meaning of the input data and outputs a 512-dimensional context vector. The processing unit inputs this context vector to a graph neural network for structural optimization. The graph neural network generates a graph structure in which each part of a robot hand is a node and a physical connection between parts is an edge. The graph neural network assigns parameters of a material and dimensions to each node. For example, the processing unit operates a reinforcement learning agent in a virtual space to determine an arrangement of a suction pad. The agent receives a position of a center of gravity and surface unevenness data of the object as input. The agent outputs optimal coordinates of the suction pad as a three-dimensional vector. The processing unit executes a stress analysis simulation based on a finite element method on the output coordinate group in the background. The processing unit incorporates a maximum stress value and a deformation amount obtained from a simulation result into a loss function. The processing unit optimizes a thickness of a part and an arrangement of a rib using a gradient descent method. The processing unit generates structured data including three-dimensional bounding box coordinates, a material ID, a degree of freedom of a connection joint, and an estimated cost value of each part as output data. The processing unit passes this output data to a subsequent three-dimensional model generation module. As a technical effect, the present system autonomously synthesizes practical mechanical design data compliant with physical laws and manufacturing requirements, rather than a mere text response. The present system solves a trade-off between multivariables that a human engineer cannot fully consider by a mathematical optimization method. As a specific application field of the present system, the present system is used in a conceptual design of an end effector at the time of starting up a new line and a redesign task of a jig for improving a yield of existing equipment.

The design proposal presentation unit transmits the plurality of design proposals generated by the generative AI processing unit to the terminal, and presents information from various viewpoints on the terminal, such as features, an appearance image, dimensions, material information, a functional description, a cost estimate, a durability evaluation, a hygiene evaluation, a mass productivity evaluation, a user evaluation prediction, legal regulation compliance, an assembly procedure, a disassembly procedure, maintainability, customizability, part replaceability, brand image compliance, on-site safety standard compliance, cooperativeness with an on-site worker, compatibility with on-site equipment, compliance with an on-site work environment, compliance with an on-site maintenance system, compliance with an on-site education system, on-site IoT connectivity, on-site data connectivity, and on-site DX promotion capability of each proposal. For example, a three-dimensional preview image, an application-specific convenience evaluation, a cost estimate, a durability evaluation, a hygiene evaluation, an assembly animation, a disassembly animation, a parts list, a material list, a processing method list, a recommended production method, a recommended distribution method, a recommended package proposal, an on-site work video simulation, a cooperative operation simulation with an on-site worker, an interference check simulation with on-site equipment, an on-site IoT linkage simulation, an on-site maintenance work simulation, and the like are also presented simultaneously. Specifically, the design proposal presentation unit renders multidimensional design data received from the server in real time using a graphics processing apparatus of the terminal. The presentation unit reads vertex data and a normal vector of the generated three-dimensional model. The presentation unit executes a shader program and draws a metallic luster and a resin texture on a screen by a physically based rendering technology. The presentation unit generates an evaluation index of each design proposal as a visual component such as a radar chart or a bar graph. The presentation unit normalizes numerical values such as cost and durability and calculates them as a score from 0 to 100. The presentation unit binds this score to a corresponding widget on a user interface. The presentation unit interpolates a transformation matrix from a local coordinate system to a global coordinate system of each part in chronological order to generate an assembly animation. The presentation unit dynamically draws a process in which parts are combined based on this interpolation data. The presentation unit constantly calculates a distance between a virtual worker model and the generated robot hand model in an on-site work video simulation. The presentation unit executes a collision determination algorithm that highlights in a warning color when the distance falls below a safety threshold. As a technical effect, the present system converts complex design data into intuitively understandable visual information. The present system enables the user to accurately evaluate validity of the design proposal without having a specialized drawing reading skill. As a specific application field of the present system, the present system is used as a presentation tool for each stakeholder to make a decision based on a common visual foundation in a design review meeting involving a management layer and an on-site operator.

A user selection unit has a function for a user to select an optimal proposal from among a plurality of presented design proposals, and allows the user to make a selection while comparing and examining a three-dimensional preview while rotating and scaling it, comparing detailed information, cost, durability, hygiene, mass productivity, legal regulation compliance, on-site IoT connectivity, on-site DX promotion capability, and the like of each proposal, and referring to a user evaluation prediction, brand image suitability, cooperativeness with an on-site worker, compatibility with on-site equipment, suitability for an on-site work environment, suitability for an on-site maintenance system, suitability for an on-site education system, on-site IoT connectivity, on-site data connectivity, on-site DX promotion capability, and the like. Furthermore, it is also possible to input an additional request or a modification instruction (for example, increasing the number of suction pads, extending the length of an arm, changing a material to stainless steel, adding a sensor, adding an IoT linkage function, adding an on-site worker detection function, adding an on-site maintenance work support function, adding an on-site DX promotion function, and the like) for the proposal selected by the user, and these pieces of information are transmitted to the generative AI processing unit again, and a new design proposal reflecting modification contents is automatically generated. Specifically, the user selection unit monitors an input event from a touch panel or a mouse of a terminal. The selection unit calculates a coordinate change amount of a swipe or pinch operation. The selection unit converts this change amount into a rotation matrix or a translation vector of a camera in a three-dimensional space. The selection unit updates a view matrix using the converted parameters to change the display of the three-dimensional model in real time. The selection unit executes a ray casting algorithm when the user clicks on a specific part. The algorithm casts a virtual ray from two-dimensional coordinates on a screen into the three-dimensional space to identify an intersecting polygon. The selection unit pop-up displays metadata of the identified part. The selection unit receives the modification instruction from the user as a natural language text or a direct editing of a parameter. The selection unit extracts the modification instruction as difference data and combines it with an original prompt vector. The selection unit transmits the combined vector to a generative artificial intelligence model of a server again. The generative artificial intelligence model holds a latent representation of a previous generation result as an initial state. The model calculates a minute movement in a latent space based on the input difference vector. The model decodes a new design proposal from the latent representation after the movement. As a technical effect, the system significantly shortens a generation time of a modified proposal by avoiding recalculation from scratch. The system realizes an interactive design iteration process that accurately reflects the user's intention. As a specific application field of the system, the system is used in face-to-face sales of a custom-made machine or an online collaborative design session in which specifications are finalized while listening to customer requests on the spot.

The three-dimensional model generation unit automatically generates a script for three-dimensional model generation usable in three-dimensional modeling software based on contents of the design proposal selected by the user. For example, it is output in a script format of an open-source three-dimensional modeling tool (Python script, STEP format, STL format, OBJ format, 3MF format, IGES format, VRML format, FBX format, and the like), and has contents for automatically generating a three-dimensional model reflecting information such as a specified shape, dimensions, material, structure, function, special function, durability, hygiene requirements, on-site safety standards, on-site IoT connectivity, and on-site DX promotion capability. For example, an arm with a suction pad, a joint portion, a sensor built-in part, a reinforcing structure, a structure capable of being disassembled and washed, an antibacterial coating portion, an IoT communication module, a self-diagnosis function portion, an on-site worker detection sensor portion, an on-site IoT linkage interface portion, an on-site maintenance work support portion, and the like are automatically arranged, and material settings reflecting dimensions and material information are also automatically performed. Specifically, the three-dimensional model generation unit parses structured data output by the generative artificial intelligence model. The generation unit maps analyzed geometric parameters of each part to a function call of a specific programming language. The generation unit constructs an abstract syntax tree and defines a hierarchical structure and a parent-child relationship of parts. The generation unit sequentially generates corresponding script codes as character strings while traversing the abstract syntax tree. For example, the generation unit describes a cylinder generation function having a radius and a height as arguments in order to generate a cylindrical arm. The generation unit inserts a code for applying a sum or a difference of a Boolean operation to a joint portion between parts. The generation unit defines a physically based rendering parameter indicating a reflectance or roughness of a material as a variable in the material setting. The generation unit generates a code for assigning the variable to a property of each part. For an electronic component such as a sensor or a communication module, the generation unit describes an instruction statement for importing a corresponding model from a standard component library prepared in advance. The generation unit generates an executable text file of several thousand lines or a CAD intermediate file in a binary format as output data. As a technical effect, the system converts conceptual design data inferred by the artificial intelligence into a standard format that can be directly incorporated into an existing manufacturing workflow. The system guarantees a seamless transition from design data to manufacturing data. As a specific application field of the system, the system is used in a process of reading the generated model as it is into finite element analysis software to perform detailed strength calculation, or directly inputting it into slicer software of a three-dimensional printer to perform rapid prototyping.

A script output unit transmits the script for three-dimensional model generation generated by the three-dimensional model generation unit to the terminal so that the user can download it or import it into external three-dimensional modeling software. For example, the user can download the script and edit and utilize it in their own design department, or directly transmit it to an external three-dimensional printer or a processing contractor. Specifically, the script output unit compresses the generated script file or CAD data using a lossless compression algorithm. The output unit applies a hash function to the compressed archive file to calculate a checksum. The output unit transfers the archive file to the terminal via a secure communication protocol. The output unit verifies that there is no data loss by collating the checksum when the download is completed on the terminal side. The output unit has a function of directly push-transmitting data to an external cloud-based CAD system or manufacturing execution system via an application programming interface. The output unit executes secure token-based access control using an authentication protocol at the time of this transmission. The output unit includes middleware that dynamically converts a data format in accordance with specifications of a destination system. As a technical effect, the system safely and efficiently links generated design assets to an external system. The system prevents data silos and constructs a digital thread from design to manufacturing. As a specific application field of the system, the system is used in a cloud manufacturing platform in which data designed by a fabless company is automatically transferred to a system of a partner processing factory to immediately perform estimation and manufacturing arrangements.

A history management unit centrally manages a user's input history, selection history, generated design proposals, scripts for three-dimensional model generation, download history, modification history, tendency data for each user, on-site feedback, on-site accident data, equipment operation data, part life prediction data, abnormality detection data, on-site work video data, on-site audio data, on-site IoT data, on-site DX data, and the like, and can automatically make a more personalized proposal by learning a preferred pad arrangement, material, cost range, brand image, on-site IoT connectivity, on-site DX promotion capability, and the like for a user who has designed a suction pad method a plurality of times in the past, for example. Specifically, the history management unit is configured by combining a distributed relational database and a non-relational database. The management unit stores structured parameter data in a table of the relational database. The management unit stores video and audio data, which are unstructured data, in an object storage and records their reference addresses in the database. The management unit accumulates an operation log for each user in a time-series database. The management unit applies collaborative filtering or a content-based recommendation algorithm to the accumulated data group. The management unit models the user's past selection tendency as a multidimensional vector. The management unit calculates a cosine similarity between the user vector and a vector of a newly generated design proposal. The management unit dynamically sorts a presentation order of design proposals based on the similarity score. The management unit fine-tunes weight parameters of the generative artificial intelligence model using feedback data from a site or part life data as training data. As a technical effect, the more the system is used, the more the system outputs a highly accurate design proposal specialized for the user's personal preference or a specific factory environment. The system accumulates design know-how, which has depended on individuals as tacit knowledge, in the system as explicit knowledge. As a specific application field of the system, the system is used as a knowledge management system that learns a design process of a skilled designer in a large company and provides design support and education to young engineers.

An external data import unit can, when a user uploads external design data, an image, a drawing, a sketch, CAD data, three-dimensional scan data, on-site work video data, on-site audio data, on-site IoT data, on-site DX data, or the like, analyze these data, comprehensively consider a specified application, constraint conditions, on-site feedback, on-site accident data, equipment operation data, part life prediction data, abnormality detection data, on-site work video data, on-site audio data, on-site IoT data, on-site DX data, and the like, automatically perform redesign and optimization in accordance with the specified application and constraint conditions, and generate a new design proposal and a script for three-dimensional model generation. For example, by uploading three-dimensional scan data of an existing end effector and giving instructions such as “add a suction pad based on this shape”, “change a material”, “enlarge dimensions”, “make it compatible with a specific part”, “add an IoT linkage function”, “add an on-site worker detection function”, “add an on-site maintenance work support function”, and “add an on-site DX promotion function”, the generative AI can automatically perform optimized design and output the script for three-dimensional model generation. Specifically, the external data import unit includes a data pipeline that normalizes uploaded data in various formats. When receiving point cloud data which is three-dimensional scan data, the import unit reduces a data size using random sampling or a voxel grid filter. The import unit inputs the point cloud data to a three-dimensional convolutional neural network. The network extracts local and global geometric features of the point cloud and outputs a fixed-length global feature vector. When receiving a two-dimensional drawing image, the import unit extracts dimension lines and annotation texts using optical character recognition technology. The import unit converts an outline into vector data using an edge detection algorithm. The import unit combines these extracted feature vectors and a modification instruction vector in natural language from the user. The import unit provides the combined vector as a conditional input to the generative artificial intelligence model. The generative artificial intelligence model executes a deformation process of rearranging vertex coordinates of a mesh so as to satisfy the specified constraint conditions while maintaining a topology of the input existing shape. As a technical effect, the system makes it possible to reuse existing physical assets and past design data in accordance with the latest requirements without wasting them. The system completely automates a reverse engineering process and dramatically shortens a design lead time. As a specific application field of the system, the system is used in maintenance work in which a replacement part for old equipment whose drawing has been lost is immediately redesigned from an actual object scan and output by a three-dimensional printer.

As described above, the system according to the present embodiment includes the user input unit, a data transmission unit, the generative AI processing unit, a design proposal presentation unit, the user selection unit, the three-dimensional model generation unit, the script output unit, the history management unit, and the external data import unit, and by operating these units in cooperation with each other, realizes a system capable of allowing a user to select an optimal one from among various design options in a short time and easily, and automatically generating a specific three-dimensional model even if the user does not have specialized three-dimensional modeling technology or knowledge. Specifically, the system implements the plurality of independent software modules by containerizing them as a microservice architecture. The system asynchronously processes communication between the containers using a message queuing protocol. The system dynamically scales computing resources according to a load status of each module using an orchestration tool. The system controls a series of data flows from user input to final script output in an event-driven manner. The system caches intermediate data generated in each processing step in an in-memory database. By this cache mechanism, the system minimizes a recalculation cost when the user returns to a previous step and changes a condition. The system executes inference processing of the artificial intelligence model and rendering processing of the three-dimensional model in parallel threads. By this parallel processing, the system maintains high responsiveness of a user interface. As a technical effect, the system consistently integrates artificial intelligence processing requiring advanced calculation and a user operation requiring real-time performance on a single platform. The system improves availability and fault tolerance of the entire system. As a specific application field of the system, the system is used as a global design sharing platform accessed simultaneously from a plurality of bases around the world or a backend system of a cloud-based integrated development environment.

### (Implementation Steps)

Step 1: User Requirement Input A user inputs information necessary for designing an arm or an end effector of a factory robot in detail using the user input unit on the terminal. For example, a rectangular parallelepiped, a cylinder, a sphere, an irregularly shaped object, a bag shape, a plate shape, a flexible object, a liquid container, a powder bag, or the like is specified as a shape of an object to be conveyed, dimensions such as a width of 40 cm×a depth of 30 cm×a height of 20 cm, a diameter of 7 cm×a height of 25 cm, a plate shape with a thickness of 2 mm, and a maximum external dimension within 100 mm are input, and a weight such as 5 kilograms, 100 grams, 20 kilograms, a maximum of 30 kilograms, and a minimum of 10 grams is specified. A size and constraints of a work space such as a width of 1 meter×a depth of 1 meter×a height of 1.5 meters, a ceiling height limit, presence or absence of an obstacle, a movable range limit, interference avoidance with adjacent equipment, a cooperative operation area with a worker, and a height limit of a conveyance line are input, and a gripping method such as a suction pad, a gripper, magnetic force, vacuum, a clamp, tweezers, a hook, a belt, a vacuum, an adhesive pad, an air blow, electrostatic adsorption, a flexible finger gripper, a multi-finger robot hand, and a soft gripper for a collaborative robot is selected. Aluminum, resin, stainless steel, carbon, rubber, a food hygiene compliant material, a heat-resistant material, a chemical-resistant material, an antistatic material, an antibacterial material, a lightweight composite material, a resin for 3D printing, or the like is specified as a desired material, and heating, cooling, a weight sensor, an image sensor, a force sensor, static electricity removal, an antibacterial coating, wear detection, a self-diagnosis function, an IoT communication function, a QR reader for workpiece identification, a workpiece automatic recognition AI, an abnormality detection AI, a remote monitoring function, a self-position correction function, an automatic part replacement function, an automated washing function, or the like is input as a necessary special function. A cost upper limit, durability, hygiene requirements, an installation space, an operation speed, mass productivity, maintainability, presence or absence of a replacement part, on-site safety standards, legal regulation compliance, a brand image, on-site specific special requirements, and the like can also be input simultaneously in plurality. Specifically, in this step, the system deploys a dynamic input form on a memory of the terminal. The system parses a text character string input by the user in real time. The system separates a numerical value and a unit using a regular expression and automatically converts them into an internal standard unit system. The system maps input categorical data to a unique identifier using a hash function. The system calls a natural language processing model when the user inputs an ambiguous expression such as a flexible object or an irregularly shaped object. The model searches for a similar object from a past database and presents specific physical parameter candidates to the user. The system constructs a plurality of input constraint conditions as a multidimensional constraint matrix on the memory. The system assigns a weighting coefficient to each element of the matrix. As a technical effect, the system converts human-specific notational fluctuations and ambiguous requirement definitions into strict mathematical expressions that can be processed by a machine. The system eliminates useless calculation in subsequent artificial intelligence processing by immediately detecting an input error on a front-end side and prompting correction. As a specific application field of this step, this step is used as an interface for an on-site worker who is not a specialized CAD operator to intuitively input requirements using a tablet terminal.
Step 2: Input Data Transmission All information input by the user input unit is transmitted to the server via the data transmission unit. Encryption of network communication, data format conversion, retransmission control at the time of a transmission error, consistency check of input data, automatic data collection from an on-site terminal, automatic transmission of on-site information by a barcode or RFID, real-time transmission of on-site IoT data, upload transmission of on-site work video and audio data, and the like are also performed simultaneously. Specifically, in this step, the system serializes the constructed constraint matrix and multimedia data into a single payload. The system encrypts the payload using an encryption protocol. The system transmits the encrypted data to an endpoint of the server as an asynchronous network request. When detecting a packet loss during transmission, the system attempts retransmission while gradually extending a retransmission interval using an exponential backoff algorithm. The system subscribes to sensor data streamed from an on-site programmable logic controller. The system divides the time-series data into a certain batch size and asynchronously merges it into the main payload. The system compresses a data size by calculating an inter-frame difference for uploaded video data and thinning out frames with little movement. As a technical effect, the system aggregates information from various data sources to the server without loss while efficiently utilizing a network bandwidth. The system ensures reliability and security of communication. As a specific application field of this step, this step is used in a process of safely transferring data to a cloud server from an overseas factory or an underground manufacturing line where communication infrastructure is fragile.
Step 3: Automatic Generation of Design Proposal by Generative AI The generative AI processing unit on the server analyzes the design requirements transmitted from the user, makes a comprehensive judgment by linking a plurality of AI modules such as natural language processing, image recognition, structural optimization, material property inference, past design database reference, user history analysis, similar case search, trend analysis, cost simulation, durability evaluation, hygiene evaluation, legal regulation compliance evaluation, on-site feedback learning, on-site accident data analysis, equipment operation data analysis, part life prediction AI, abnormality detection AI, on-site work video analysis AI, and on-site audio analysis AI, and automatically generates a plurality of design proposals optimized for the application and the constraint conditions. For example, when the suction pad method is specified, a surface state and weight of the object, a conveyance speed, constraints of the work space, hygiene requirements, on-site temperature and humidity conditions, an on-site dust/oil/moisture environment, a wear/deterioration/replacement history of the suction pad, power consumption/noise/maintenance history of a vacuum generation mechanism, chemical resistance/heat resistance/wear resistance of a pad material, pad replaceability, pad washability, a pad wear detection function, a vacuum leak detection function, an optimal layout of vacuum piping, selection of a vacuum generation source, a vacuum pressure control algorithm, an automatic adjustment function of suction force, a recovery operation at the time of suction failure, an automatic cleaning mechanism of the suction pad, an automatic replacement mechanism of the suction pad, inventory management linkage of the suction pad, and the like are automatically designed. Specific examples of a prompt sentence to be read by the generative AI include “Object: rectangular parallelepiped cardboard box, dimensions 40 cm×30 cm×20 cm, weight 5 kilograms, work space: width 1 meter×depth 1 meter×height 1.5 meters, gripping method: suction pad, material: aluminum, special function: built-in weight sensor, cost upper limit: 100,000 yen, durability: 100,000 cycles or more, hygiene requirements: food factory compliant, installation space: maximum external dimension within 1.2 meters, operation speed: 1 cycle within 3 seconds, mass productivity: part standardization, maintainability: capable of being disassembled and washed, replacement part: suction pad replaceable, on-site safety standards: collaborative robot standard compliant, legal regulation: Food Sanitation Act compliant, brand image: corporate logo engraved”, and the like. Specifically, in this step, the system deserializes the received payload and distributes data to each artificial intelligence module. The system infers a design intention and hidden constraint conditions from the prompt sentence using a large language model. The system inputs an inference result to a generator network as a condition vector in a latent space. The generator network adopts an architecture of a variational autoencoder. The network combines a noise vector sampled from a normal distribution and the condition vector. The network outputs an occupancy probability of each cell of a three-dimensional voxel grid from the combined vector. The system extracts a smooth polygon mesh by applying a marching cubes method to the output probability distribution. The system applies a topology optimization algorithm to the generated mesh. The algorithm iteratively reduces an unnecessary volume while satisfying specified weight and stress conditions. The system generates three-dimensional shape data of each design proposal, a bill of materials, and a list of estimated performance scores as output data. The system passes the output data to a subsequent presentation step. As a technical effect, the system creates a lightweight and high-strength atypical shape, which is difficult to reach by human intuition, based on mathematical grounds. The system searches for a set of Pareto optimal solutions satisfying a plurality of constraint conditions simultaneously in a short time. As a specific application field of this step, this step is used in a lightweight design of a part in the aerospace industry or the automobile industry, or an automatic design process of an innovative robot hand incorporating biomimetics.
Step 4: Design Proposal Presentation and User Selection. A plurality of design proposals generated by the generative AI processing unit are transmitted to the terminal via a design proposal presentation unit, and information from diverse viewpoints is presented on the terminal, such as features of each proposal, an appearance image, dimensions, material information, a functional description, a cost estimate, a durability evaluation, a hygiene evaluation, a mass productivity evaluation, a user evaluation prediction, legal regulation compliance, an assembly procedure, a disassembly procedure, maintainability, customizability, part replaceability, brand image compliance, on-site safety standard compliance, cooperativeness with on-site workers, compatibility with on-site equipment, suitability for an on-site work environment, suitability for an on-site maintenance system, suitability for an on-site education system, on-site IoT connectivity, on-site data connectivity, and on-site DX promotion capability. The user selects an optimal design proposal while referring to a three-dimensional preview image, a convenience evaluation by application, a cost estimate, a durability evaluation, a hygiene evaluation, an assembly animation, a disassembly animation, a parts list, a material list, a processing method list, a recommended production method, a recommended distribution method, a recommended package proposal, an on-site work video simulation, a cooperative operation simulation with on-site workers, an interference check simulation with on-site equipment, an on-site IoT linkage simulation, an on-site maintenance work simulation, and the like. Specifically, in this step, the system caches the plurality of design proposal data transmitted from the server in a local storage of the terminal. The system calls a graphics processing interface and renders the three-dimensional model on a browser using hardware acceleration. The system analyzes metadata of each design proposal and arranges various indicators in a graph on a dashboard on a user interface. When the user mouses over a specific design proposal, the system summarizes features of the proposal using a natural language generation model and displays the summary as a tooltip. Upon receiving a playback request for a simulation video, the system reads kinematics data pre-calculated on the server side. Based on this data, the system updates joint angles of the robot arm over time and animates the model on the screen. When the user presses a selection button, the system acquires a unique identifier of the design proposal. The system stores this identifier in a state management module and fires a trigger to shift to subsequent processing. As a technical effect, the system organizes and presents multidimensional design data having a huge amount of information in a form that reduces a cognitive load on the user. The system assists the user in making a data-driven objective decision. As a specific application field of this step, this step is used in a competition of a procurement department or a design review meeting for selecting one having the best balance between cost and performance from among a plurality of design proposals.
Step 5: Input of Additional Request/Correction Instruction and Regeneration. The user can input an additional request or a correction instruction (for example, increasing the number of suction pads, extending the length of the arm, changing the material to stainless steel, adding a sensor, adding an IoT linkage function, adding an on-site worker detection function, adding an on-site maintenance work support function, adding an on-site DX promotion function, etc.) for the selected design proposal, and this information is transmitted to the generative AI processing unit again, and a new design proposal reflecting the correction contents is automatically generated. Specific examples of a prompt sentence to be read by the generative AI include “Object: rectangular cardboard box, dimensions 40 cm×30 cm×20 cm, weight 5 kg, work space: width 1 m×depth 1 m×height 1.5 m, gripping method: suction pad, material: stainless steel, special function: built-in weight sensor, addition of IoT linkage function, cost upper limit: 120,000 yen, durability: 150,000 cycles or more, hygiene requirement: food factory compliance, installation space: maximum external dimensions within 1.2 m, operation speed: within 2.5 seconds per cycle, mass productivity: part standardization, maintainability: disassemblable and washable, replacement part: replaceable suction pad, on-site safety standard: collaborative robot standard compliance, legal regulation: Food Sanitation Act compliance, brand image: corporate logo engraving”. Specifically, in this step, the system inputs the correction text input by the user into a natural language processing model and executes intent extraction. The system classifies the extracted intent into an operation category such as a parameter change or a part addition. The system adds a latent vector of the original design proposal and the classified operation vector in a vector space. The system inputs this added vector to a decoder network to generate a new three-dimensional shape. For example, in response to an instruction to increase the number of suction pads, the system re-executes a pad arrangement algorithm. This algorithm recalculates a surface area and a center of gravity position of the object and rearranges an optimal coordinate group of the pads. In response to a material change instruction, the system issues a query to a material database and acquires a density and a Young's modulus of a new material. Using these physical properties, the system re-executes a stress analysis simulation and automatically recalculates a necessary thickness. The system highlights the regenerated design proposal as a difference from the original proposal. As a technical effect, the system automatically translates the user's abstract request into a specific physical parameter change. The system eliminates manual correction work of a CAD model and dramatically improves a design iteration speed. As a specific application field of this step, this step is used in an agile product development process in which an improvement request raised from the site in response to a test result of a prototype is immediately reflected in design data.
Step 6: Automatic Generation of Script for Three-Dimensional Model Generation. Based on the contents of the design proposal finally selected by the user, the three-dimensional model generation unit on the server automatically generates a script for three-dimensional model generation usable in three-dimensional modeling software. For example, it is output in a script format of an open-source three-dimensional modeling tool (Python script, STEP format, STL format, OBJ format, 3MF format, IGES format, VRML format, FBX format, etc.), and has contents for automatically generating a three-dimensional model reflecting information such as the specified shape, dimensions, material, structure, function, special function, durability, hygiene requirement, on-site safety standard, on-site IoT connectivity, and on-site DX promotion capability. Specifically, in this step, the system scans an internal data structure of the finalized design proposal. The system converts geometric information of each part into a boundary representation model. Based on this boundary representation model, the system generates text data in accordance with syntax rules of a specified output format. When outputting a scripting language, the system sequentially describes function calls for generating each part. The system optimizes a generation code of regularly arranged parts using loop processing and conditional branching. When outputting a standard three-dimensional data format, the system describes an entity definition compliant with an international standard. The system strictly defines a topological relationship of faces, edges, and vertices of each part. The system embeds a density of the material, creator information, and the like as metadata in a file header. The system executes a syntax checker on the generated script code to verify that there is no error. As a technical effect, the system converts a unique data format generated by artificial intelligence into a versatile industry standard format. The system realizes open data linkage independent of software of a specific vendor. As a specific application field of this step, this step is used in a process of passing the generated data to a downstream manufacturing support system to automatically generate a tool path of a machine tool, or a process of providing a base model for constructing a digital twin of a product.
Step 7: Output and Download of Script. The script for three-dimensional model generation generated by the three-dimensional model generation unit is transmitted to the terminal via a script output unit, and the user can download the script to edit and utilize it in their own design department, or directly transmit it to an external three-dimensional printer or a processing contractor. Specifically, in this step, the system saves the generated script file in a temporary storage of the server. The system generates a unique download address for this file. The system transmits this address to the terminal. Upon receiving a data acquisition request from the terminal, the system divides the file into chunks and performs streaming transfer. The system deletes the file from the temporary storage after the transfer is completed to ensure security. When directly transmitting to an external three-dimensional printer, the system specifies a network address of the printer and establishes socket communication. The system calls an interface of slicer software and remotely executes a process of converting the generated model data into a machine control code. When transmitting to a processing contractor, the system automatically uploads the file to a server of the contractor using an encrypted communication path. As a technical effect, the system eliminates manual work associated with delivery of design data and prevents data mix-ups and leakage due to human error. The system minimizes a time lag from completion of design to start of manufacturing. As a specific application field of this step, this step is used in a seamless supply chain management system that links with an on-demand manufacturing service and automatically performs an ordering process simultaneously with the completion of design.
Step 8: History Management and External Data Import. A history management unit centrally manages a user's input history, selection history, generated design proposals, scripts for three-dimensional model generation, download history, correction history, trend data for each user, on-site feedback, on-site accident data, equipment operation data, part life prediction data, abnormality detection data, on-site work video data, on-site audio data, on-site IoT data, on-site DX data, and the like, and when the user uploads external design data, an image, a drawing, a sketch, CAD data, three-dimensional scan data, on-site work video data, on-site audio data, on-site IoT data, on-site DX data, or the like, an external data import unit analyzes these data, comprehensively considers the specified application and constraint conditions, on-site feedback, on-site accident data, equipment operation data, part life prediction data, abnormality detection data, on-site work video data, on-site audio data, on-site IoT data, on-site DX data, and the like, automatically performs redesign and optimization in accordance with the specified application and constraint conditions, and can generate a new design proposal and a script for three-dimensional model generation. Specifically, in this step, the system asynchronously writes all transaction data generated in a series of sessions to a data lake. The system executes a machine learning pipeline on this accumulated big data by batch processing. The system performs regression analysis using on-site abnormality detection data and part life prediction data as objective variables and design parameters as explanatory variables. From this analysis result, the system extracts a correlation in which a specific shape or material causes a failure. The system adds this extracted rule as a penalty term to a loss function of a generative artificial intelligence model. The system applies an iterative closest point algorithm to three-dimensional scan data uploaded from the outside to perform alignment with an existing standard part model. The system calculates a difference between the scan data and the standard model to quantify a degree of wear or deformation. The system automatically offset-corrects the original design data so as to compensate for this wear data. As a technical effect, the system constructs a closed-loop continuous improvement cycle that feeds back actual data obtained in an operation phase to a design phase. The system sublimates from a static design tool to a self-evolving engineering platform. As a specific application field of this step, this step is used in a predictive maintenance-linked product lifecycle management system that automatically optimizes the design of a next-generation model based on sensor data collected from operating equipment.

### (Specific Use Case)

For example, assume a case where it is necessary to design a robot arm and an end effector optimized for a process of loading products in cardboard boxes onto a pallet in an automatic conveyance line of a food factory. An object to be conveyed is a rectangular cardboard box, and dimensions are 40 centimeters in width, 30 centimeters in depth, and 20 centimeters in height, and a weight is 5 kilograms. A work space is 1 meter in width, 1 meter in depth, and 1.5 meters in height, and a ceiling height restriction and interference avoidance with adjacent equipment are also required. As a gripping method, a suction pad method capable of reliably conveying the cardboard box without damaging the surface thereof is required. The material is basically aluminum, and silicone rubber compliant with food hygiene is specified for a suction pad portion. As special functions, detection of a suction state and confirmation of the weight of the box by a weight sensor, real-time transmission of operation data by IoT communication, wear detection and an automatic replacement function of the suction pad, a disassemblable and washable structure, an antibacterial coating, cooperative operation detection with an on-site worker, an automatic stop function at the time of abnormality, a self-diagnosis function for on-site maintenance work support, and the like are required. A cost upper limit is 150,000 yen per unit, durability is 200,000 cycles or more, hygiene requirements are food factory compliance, cleaning liquid resistance, disassemblability and washability, and a foreign matter mixing prevention structure, an on-site safety standard is compliance with a collaborative robot standard, legal regulations are compliance with the Food Sanitation Act and CE marking, and a brand image is engraving of a corporate logo and adoption of a brand color. Specifically, the system acquires the extremely multidimensional and complex design requirements as described above not as simple text information but as structured data processable by a computer. A data acquisition unit analyzes a requirement definition text described in natural language using a large language model. The large language model adopts a transformer architecture. The large language model tokenizes the input text. The large language model converts each token into a high-dimensional word embedding vector. The large language model extracts each parameter constituting the design requirements. By this extraction process, a dimension requirement is expressed as a three-dimensional numerical vector. A weight requirement is expressed as a scalar value. A material requirement is expressed as an index value of a material database. A special function requirement is expressed as an array of binary flags indicating the presence or absence of each function. The system integrates these extracted parameters. The system expands the integrated parameters on a memory as one design requirement tensor. This design requirement tensor functions as input data to a subsequent generative AI module. This processing method is fundamentally different from a conventional mental process in which a human designer reads and understands a specification. This processing method eliminates ambiguity of natural language. This processing method converts the design requirements into a strict mathematical expression. Thereby, the system enables a high-speed and comprehensive search by a computer in a subsequent design proposal generation process. As a technical effect, misinterpretation of design requirements is reduced. As a technical effect, accuracy of data processing in an initial stage of a design process is dramatically improved. As a specific application field, this method is not limited to the design of a robot end effector for a food factory. This method is applicable to the design of an automatic assembly line for automobile parts. This method is also applicable to the design of a wafer conveyance mechanism of a semiconductor manufacturing apparatus.

The user inputs all the above requirements in detail in the user input unit on the terminal. As an input example, it is specified as “Object: rectangular cardboard box, dimensions 40 cm×30 cm×20 cm, weight 5 kg, work space: width 1 m×depth 1 m×height 1.5 m, gripping method: suction pad, material: aluminum and food hygiene compliant silicone rubber, special function: suction state detection, weight sensor, IoT communication, suction pad wear detection, automatic replacement, disassemblable and washable, antibacterial coating, cooperative operation detection, automatic stop at abnormality, self-diagnosis, cost upper limit: 150,000 yen, durability: 200,000 cycles or more, hygiene requirement: food factory compliance, cleaning liquid resistance, disassemblability and washability, foreign matter mixing prevention, on-site safety standard: collaborative robot standard compliance, legal regulation: Food Sanitation Act/CE marking compliance, brand image: corporate logo engraving/brand color adoption”. Specifically, the user input unit of the terminal preprocesses the input text data in real time. A preprocessing unit removes unnecessary symbols and spaces from the input text. The preprocessing unit normalizes the text. The preprocessing unit divides the normalized text in units of characters or words. The preprocessing unit stores the divided data as a one-dimensional array in a buffer memory. The terminal transmits this one-dimensional array to the server via a communication interface. In this transmission process, the terminal encrypts the data. The terminal ensures safety of data transfer using a secure communication protocol. A receiving unit of the server receives the encrypted data. The receiving unit decrypts the data. The server inputs the decrypted text data to a natural language processing engine. The natural language processing engine includes a pre-trained neural network. The neural network extracts design parameters from the input text data. For example, an input to the neural network is a 512-dimensional vector sequence obtained by tokenizing the text character string of the above input example. An output from the neural network is structured data consisting of key-value pairs corresponding to each design item. As a specific example of the output, a numerical array of width 40, depth 30, and height 20 is output for a dimension key. A numerical value of 5 is output for a weight key. Identifiers indicating aluminum and silicone rubber are output for a material key. The server temporarily saves this structured data in a database. The server uses this structured data as an initial condition for a subsequent three-dimensional model generation process. This processing method automatically converts a user's free description input into a strict data format directly processable by a computer. This processing method does not replace conventional manual data input work by a human. This processing method automates a structuring process of input data itself, and fundamentally improves efficiency of data processing. As a technical effect, parsing processing of input data is accelerated. As a technical effect, an error in data delivery to a subsequent design algorithm is eliminated. As a specific application field, this input interface is applicable to a design system for an industrial robot. This input interface is also applicable to a requirement definition system for a custom-made medical instrument.

This input information is transmitted to the server via a data transmission unit, and the generative AI processing unit automatically generates a plurality of design proposals by comprehensively considering the number and arrangement of suction pads, a length and a movable range of the arm, a structure of a joint portion, a material and a thickness of the suction pad, selection of a vacuum generation mechanism, arrangement of a weight sensor, incorporation of an IoT communication module, installation of a wear detection sensor, design of a disassemblable and washable structure, application of an antibacterial coating, arrangement of a sensor for cooperative operation detection, design of an automatic stop mechanism at the time of abnormality, incorporation of a self-diagnosis algorithm, cost, durability, hygiene, on-site safety standards, legal regulations, a brand image, and the like. For example, diverse variations are presented, such as a proposal in which four suction pads are arranged, a proposal in which six suction pads are arranged, a proposal in which the arm is of a telescopic type, a proposal in which an automatic replacement mechanism of the suction pad is strengthened, a proposal in which an IoT communication function is expanded, a proposal in which disassemblability and washability are given top priority, a proposal in which a range of the antibacterial coating is expanded, and a proposal in which cooperative operation detection with an on-site worker is highly accurate. Specifically, the generative AI processing unit of the server has an ensemble architecture combining a plurality of deep learning models. The generative AI processing unit receives the input structured data as a design requirement tensor. The generative AI processing unit uses this design requirement tensor as a conditioning vector. The generative AI processing unit generates a latent representation of a three-dimensional shape using a conditional generative adversarial network. An input to the generative network is a 384-dimensional tensor obtained by combining a 128-dimensional normal random number vector and a 256-dimensional conditioning vector. The generative network includes a plurality of fully connected layers and a three-dimensional deconvolution layer. The generative network generates three-dimensional voxel data or point cloud data from the input tensor. An output from the generative network is, for example, a three-dimensional voxel grid having a resolution of 64×64×64. Each voxel has a probability value indicating the presence or absence and type of material. The generative AI processing unit evaluates the generated three-dimensional shape using a physical simulation engine. This evaluation process calculates a stress distribution and a deformation amount using a finite element method. This evaluation process calculates a suction force of a vacuum suction pad using fluid analysis. The generative AI processing unit uses these physical evaluation results as a reward signal. The generative AI processing unit updates a weight parameter of the generative network using a reinforcement learning algorithm. The reinforcement learning algorithm adopts a proximal policy optimization method. The generative AI processing unit calculates a manufacturing cost of each design proposal using a cost prediction model. The cost prediction model is based on a gradient boosting decision tree algorithm trained using past manufacturing data. The generative AI processing unit extracts a plurality of design proposals on a Pareto optimal boundary based on these plurality of evaluation indicators. By this extraction process, diverse variations having different suction pad arrangements and arm structures are generated. This processing method discovers an optimal solution difficult to reach by human intuition in a high-dimensional design space by mathematical search. This processing method replaces a conventional trial-and-error design process with a parallel and comprehensive optimization process by a computer. As a technical effect, a generation speed of a design proposal is dramatically improved. As a technical effect, a high-quality design proposal satisfying a physical constraint and a cost constraint at the same time is stably obtained. As a specific application field, this generation process is applicable to the design of a robot end effector. This generation process is also applicable to topology optimization design of a lightweight part of an aircraft.

The user compares a three-dimensional preview, dimensions, a material, a function, a cost estimate, a durability evaluation, a hygiene evaluation, an assembly/disassembly animation, a parts list, an on-site simulation video, an IoT linkage evaluation, the presence or absence of an on-site maintenance work support function, brand image compliance, and the like of each design proposal on the terminal, and selects an optimal design proposal. Furthermore, the user can input an additional request or a correction instruction such as “increase the number of suction pads”, “extend the length of the arm by 10 cm”, “strengthen the IoT communication function”, “further improve disassemblability and washability”, and “change the position of the brand logo”, and automatically generate a design proposal by the generative AI again. Specifically, a display control unit of the terminal renders the plurality of design proposal data received from the server on a graphical user interface. The display control unit renders the three-dimensional model at high speed on a browser using a web-based three-dimensional graphics rendering technology. The display control unit executes rotation, enlargement, and reduction of the three-dimensional model in real time in accordance with a user operation. The terminal visualizes an evaluation indicator of each design proposal as a radar chart or a bar graph. An input receiving unit of the terminal receives an additional request or a correction instruction from the user as a natural language text or a direct change of a parameter. The terminal converts the received correction instruction into a difference vector. The terminal transmits this difference vector to the server. The generative AI processing unit of the server updates the conditioning vector using the received difference vector. The generative AI processing unit re-inputs the updated conditioning vector to the generative network. In this regeneration process, the generative AI processing unit uses a latent representation of a previous generation result as an initial value. By this initial value setting, the generative AI processing unit executes a local shape change in accordance with the correction instruction while maintaining a basic structure of the design proposal selected by the user. For example, when an instruction to increase the number of suction pads is input, the generative AI processing unit recalculates a voxel arrangement probability of a bottom surface region of the end effector. The generative AI processing unit rearranges optimal pad arrangement coordinates while avoiding interference. This processing method directly maps the user's intent to a latent space of a generative model as a mathematical constraint condition. This processing method realizes an interactive optimization process between a human and a computer. As a technical effect, a convergence speed of a design proposal with respect to a user's request is improved. As a technical effect, a calculation cost required for fine adjustment of design is reduced. As a specific application field, this interactive design interface is applicable to customized design of industrial equipment. This interactive design interface is also applicable to an online order system for personalized products for consumers.

Regarding the finally selected design proposal, the three-dimensional model generation unit automatically generates a script for three-dimensional model generation (such as a Python script, a STEP format, or an STL format) usable in three-dimensional modeling software, and the user can download this script to immediately generate a three-dimensional model. A specific example of a prompt sentence to be read by the generative AI is “Object: rectangular cardboard box, dimensions 40 cm×30 cm×20 cm, weight 5 kg, work space: width 1 meter×depth 1 meter×height 1.5 meters, gripping method: suction pad, material: aluminum and food hygiene compliant silicone rubber, special function: suction state detection, weight sensor, IoT communication, suction pad wear detection, automatic replacement, disassemblable and washable, antibacterial coating, cooperative operation detection, automatic stop at abnormality, self-diagnosis, cost upper limit: 150,000 yen, durability: 200,000 cycles or more, hygiene requirements: food factory compliant, cleaning liquid resistance, disassemblability and washability, foreign matter contamination prevention, site safety standard: collaborative robot standard compliant, legal regulation: Food Sanitation Act/CE marking compliant, brand image: corporate logo engraving/brand color adoption”. Specifically, the three-dimensional model generation unit of the server converts voxel data or point cloud data of the finalized design proposal into a boundary representation model. In this conversion process, the three-dimensional model generation unit extracts an isosurface using a marching cubes method. The three-dimensional model generation unit smoothes vertex coordinates of the extracted polygon mesh. The three-dimensional model generation unit fits the smoothed mesh data to an analytic geometric curved surface patch. The three-dimensional model generation unit constructs a solid model based on the fitted curved surface data. The three-dimensional model generation unit extracts each feature of the constructed solid model. The three-dimensional model generation unit constructs a history of the extracted features as an abstract syntax tree on a memory. The three-dimensional model generation unit scans this abstract syntax tree. The three-dimensional model generation unit generates a program code for calling an application programming interface of specific three-dimensional CAD software based on a scanning result. A transformer-based language model specialized for code generation is used for this program code generation. Inputs to this language model are node information of the abstract syntax tree and specification data of the target CAD software. An output from this language model is text data of an executable script language. As a specific example of the output, a code block of a function call that generates a cylinder at specific coordinates and applies a fillet with a specified radius is included. The server compresses the generated script file and a file of a standard three-dimensional data exchange format. The server provides the compressed file to the terminal in a downloadable format. This processing method is not limited to mere output of shape data, but automatically generates a parametric CAD model retaining a design history. This processing method facilitates a design change in a post-process. As a technical effect, a conversion process from design data to manufacturing data is completely automated. As a technical effect, a problem of data compatibility between different CAD systems is solved. As a specific application field, this script generation technology is applicable to automation of mold design. This script generation technology is also applicable to automatic generation of building information modeling data for architecture.

In this way, by using the system of the present invention, even a user without specialized knowledge can realize design and prototyping of an arm or an end effector of a factory robot in accordance with detailed requirements for each site in a short period of time and with high accuracy, and it is possible to flexibly and efficiently respond to diverse site needs such as design verification, simulation before site introduction, prototyping before mass production, construction of a site maintenance system, site IoT cooperation, and DX promotion. Specifically, the system utilizes a distributed processing architecture constructed on a cloud computing environment. The system executes a search of a vast design space and a physical simulation in real time by a parallel computing cluster using a plurality of image processing semiconductors. The system tightly couples a generative AI module and a physical simulation module. By this tight coupling, the system forms a closed-loop control system that iteratively executes generation of a shape and evaluation of performance. This closed-loop control system solves an optimization problem that maximizes fitness of a design proposal as an objective function. The system accumulates design data obtained in each iteration step in a time-series database. The system utilizes the accumulated data as a dataset for retraining a next-generation generative model. This retraining process uses a self-supervised learning method. By this retraining process, a design generation capability of the system continuously improves. This processing method sublimates a conventional design work that has relied on human experience and intuition into a data-driven and computer-led autonomous engineering process. This processing method is an advanced information processing technology combining specific rule-based processing and unconventional procedures. As a technical effect, a lead time from design to manufacturing is dramatically shortened. As a technical effect, it becomes possible to quantitatively predict and eliminate a risk of a manufacturing defect or performance non-achievement at an initial stage of design. As a specific application field, this integrated design system is applicable as an essential base technology for constructing a smart factory premised on high-mix low-volume production. This integrated design system is also applicable as a part of a platform that digitizes an entire supply chain.

The specific processing unit 290 sends the results of specific processing obtained in Example 1 or Application Example 1 described above to the smart device 14. In the smart device 14, the control unit 46A causes the output device 40 to output the results of specific processing. The microphone 38B acquires voice indicating user input in response to the results of specific processing. The control unit 46A sends the voice data indicating user input acquired by the microphone 38B to the data processing device 12. In the data processing device 12, the specific processing unit 290 acquires the voice data.

The data generation model 58 is a so-called generative AI (Artificial Intelligence).

An example of the data generation model 58 is a generative AI such as ChatGPT (registered trademark) (Internet search <URL: https://openai.com/blog/chatgpt>).

The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

Moreover, the processing by the data processing system 10 described above is executed by the specific processing unit 290 of the data processing device 12 or the control unit 46A of the smart device 14, but it may be executed by both the specific processing unit 290 of the data processing device 12 and the control unit 46A of the smart device 14. Additionally, the specific processing unit 290 of the data processing device 12 acquires or collects necessary information for processing from the smart device 14 or external devices, and the smart device 14 acquires or collects necessary information for processing from the data processing device 12 or external devices.

In the above embodiments, an example form where specific processing is performed by the data processing device 12 was described, but the technology disclosed herein is not limited to this, and specific processing may be performed by the smart device 14.

### Second Embodiment

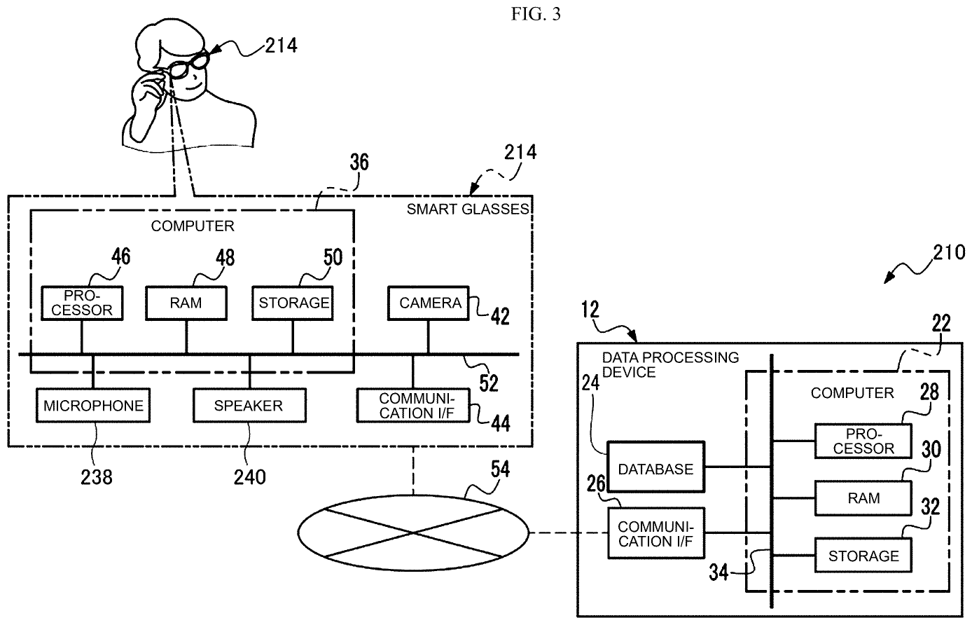

FIG. 3 shows an example configuration of a data processing system 210 according to the second embodiment.

As shown in FIG. 3, the data processing system 210 comprises a data processing device 12 and smart glasses 214. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The smart glasses 214 comprise a computer 36, a microphone 238, a speaker 240, a camera 42, and a communication I/F 44. The computer 36 comprises a processor 46, RAM 48, and storage 50. The processor 46, RAM 48, and storage 50 are connected to a bus 52. The microphone 238, speaker 240, camera 42, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

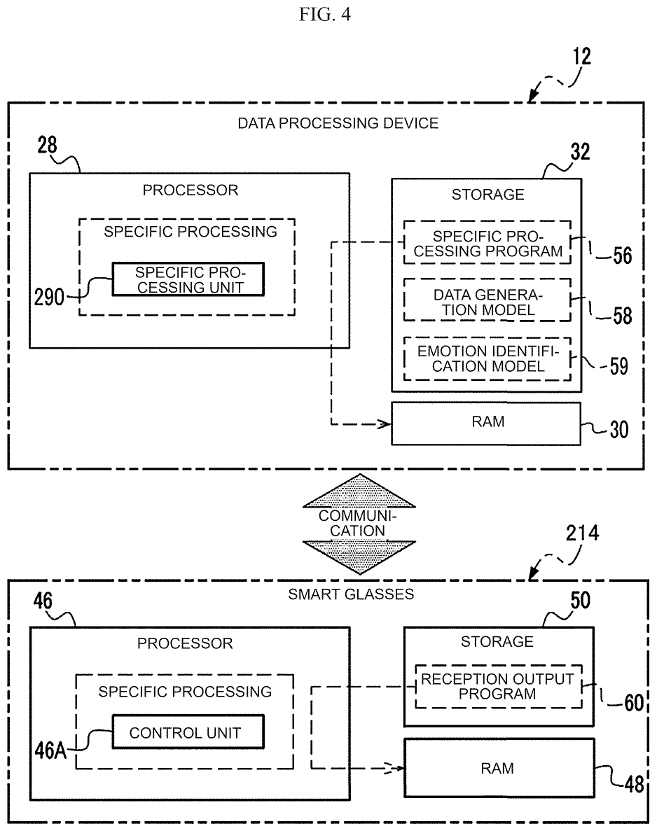

FIG. 4 shows an example of the main functions of the data processing device 12 and smart glasses 214. As shown in FIG. 4, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, and various estimations and predictions related to the user's emotions are performed, but it is not limited to such examples. Furthermore, emotion estimation and prediction may include, for example, emotion analysis.

In the smart glasses 214, reception output processing is performed by the processor 46. The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48. The smart glasses 214 may also have similar data generation models and emotion identification models as the data generation model 58 and emotion identification model 59, and perform the same processing as the specific processing unit 290 using these models.

Next, specific processing by the specific processing unit 290 of the data processing device 12 will be described. Each part of the system described below is realized by the data processing device 12 and the smart glasses 214. In the following description, the data processing device 12 is referred to as a “server,” and the smart glasses 214 are referred to as a “terminal.”

### (Example 1)

Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the smart glasses 214. In the smart glasses 214, the control unit 46A causes the speaker 240 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the smart glasses 214, but it may be executed by both the specific processing unit 290 of the data processing device 12 and the control unit 46A of the smart glasses 214. Additionally, the specific processing unit 290 of the data processing device 12 acquires or collects necessary information for processing from the smart glasses 214 or external devices, and the smart glasses 214 acquires or collects necessary information for processing from the data processing device 12 or external devices.

In the above embodiments, an example form where specific processing is performed by the data processing device 12 was described, but the technology disclosed herein is not limited to this, and specific processing may be performed by the smart glasses 214.

### Third Embodiment

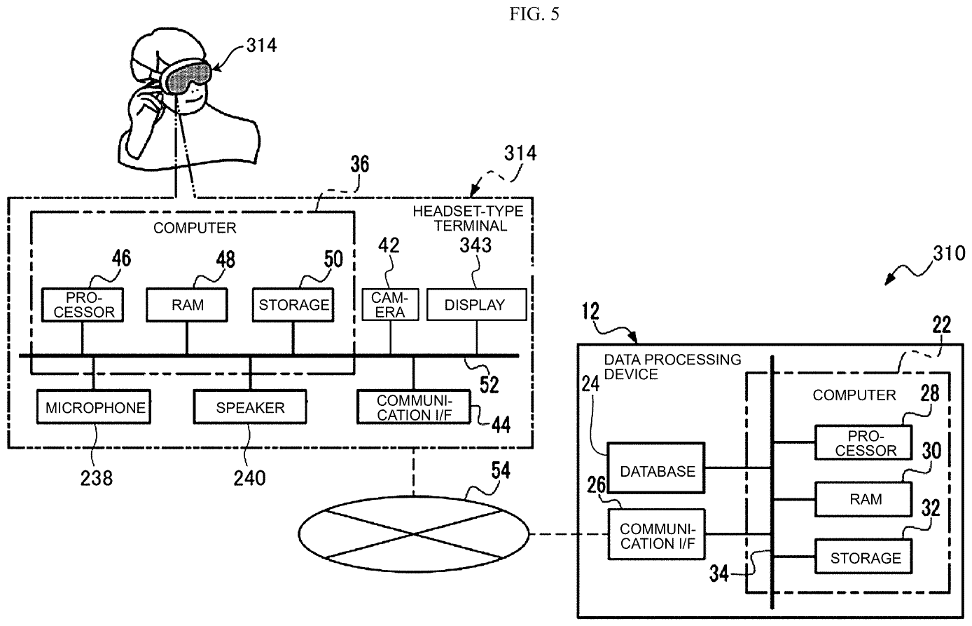

FIG. 5 shows an example configuration of a data processing system 310 according to the third embodiment.

As shown in FIG. 5, the data processing system 310 comprises a data processing device 12 and a headset-type terminal 314. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The headset-type terminal 314 comprises a computer 36, a microphone 238, a speaker 240, a camera 42, a communication I/F 44, and a display 343. The computer 36 comprises a processor 46, RAM 48, and storage 50. The processor 46, RAM 48, and storage 50 are connected to a bus 52. The microphone 238, speaker 240, camera 42, display 343, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

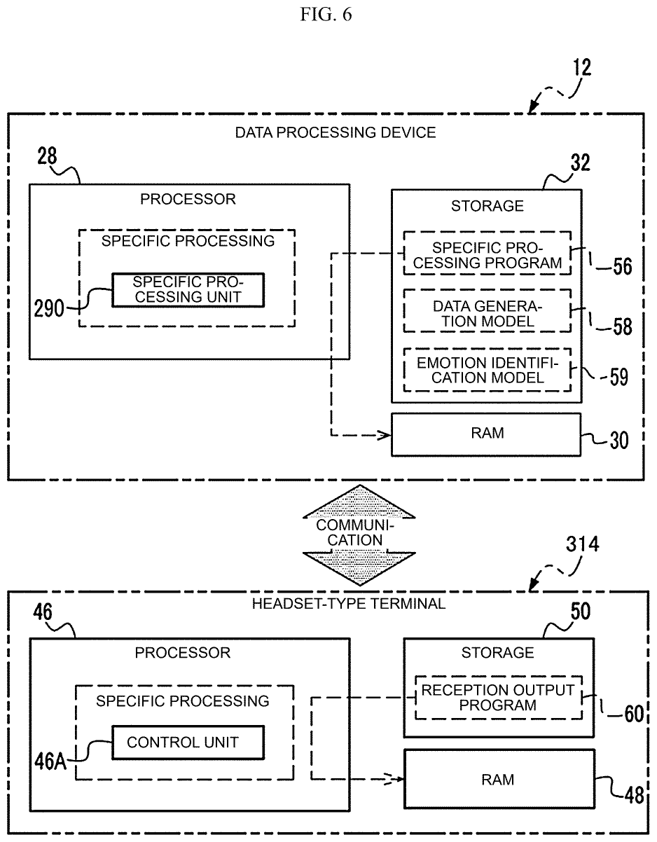

FIG. 6 shows an example of the main functions of the data processing device 12 and the headset-type terminal 314. As shown in FIG. 6, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290.

In the headset-type terminal 314, reception output processing is performed by the processor 46.

The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48.

Next, specific processing by the specific processing unit 290 of the data processing device 12 will be described. Each part of the system described below is realized by the data processing device 12 and the headset-type terminal 314. In the following description, the data processing device 12 is referred to as a “server,” and the headset-type terminal 314 is referred to as a “terminal.”

(Example 1) Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the headset-type terminal 314. In the headset-type terminal 314, the control unit 46A causes the speaker 240 and the display 343 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the headset-type terminal 314, but it may be executed by both the specific processing unit 290 of the data processing device 12 and the control unit 46A of the headset-type terminal 314. Additionally, the specific processing unit 290 of the data processing device 12 acquires or collects necessary information for processing from the headset-type terminal 314 or external devices, and the headset-type terminal 314 acquires or collects necessary information for processing from the data processing device 12 or external devices.

In the above embodiments, an example form where specific processing is performed by the data processing device 12 was described, but the technology disclosed herein is not limited to this, and specific processing may be performed by the headset-type terminal 314.

### Fourth Embodiment

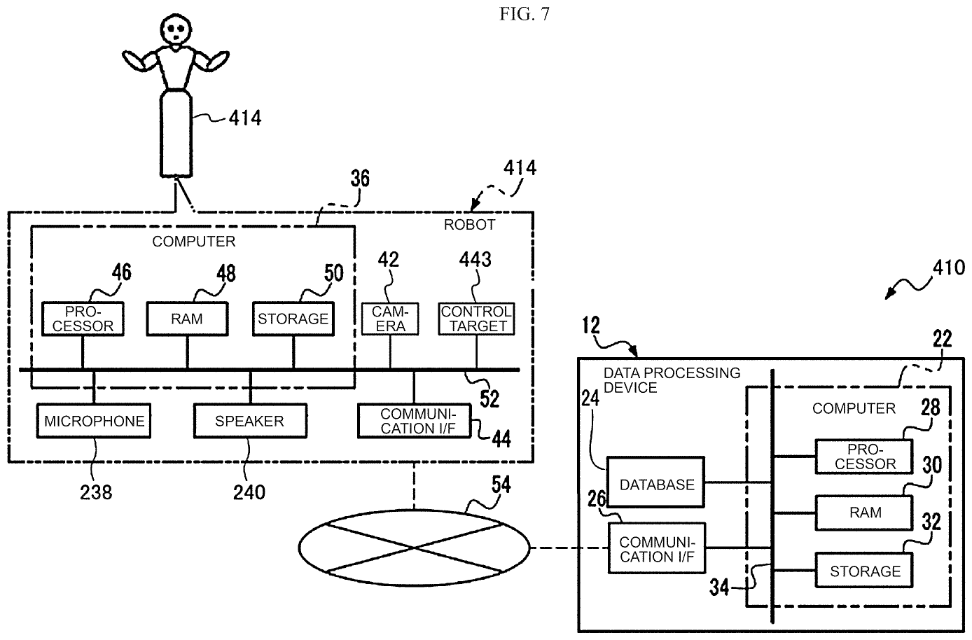

FIG. 7 shows an example configuration of a data processing system 410 according to the fourth embodiment.

As shown in FIG. 7, the data processing system 410 comprises a data processing device 12 and a robot 414. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The robot 414 comprises a computer 36, a microphone 238, a speaker 240, a camera 42, a communication I/F 44, and a control target 443. The computer 36 comprises a processor 46, RAM 48, and storage 50. The processor 46, RAM 48, and storage 50 are connected to a bus 52. The microphone 238, speaker 240, camera 42, control target 443, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

The control target 443 includes a display device, LEDs for the eyes, and motors for driving arms, hands, and feet, among others. The posture and gestures of the robot 414 are controlled by controlling the motors for the arms, hands, and feet, among others. Some emotions of the robot 414 can be expressed by controlling these motors. Additionally, the expression of the robot 414 can be expressed by controlling the lighting state of the LEDs for the eyes of the robot 414.

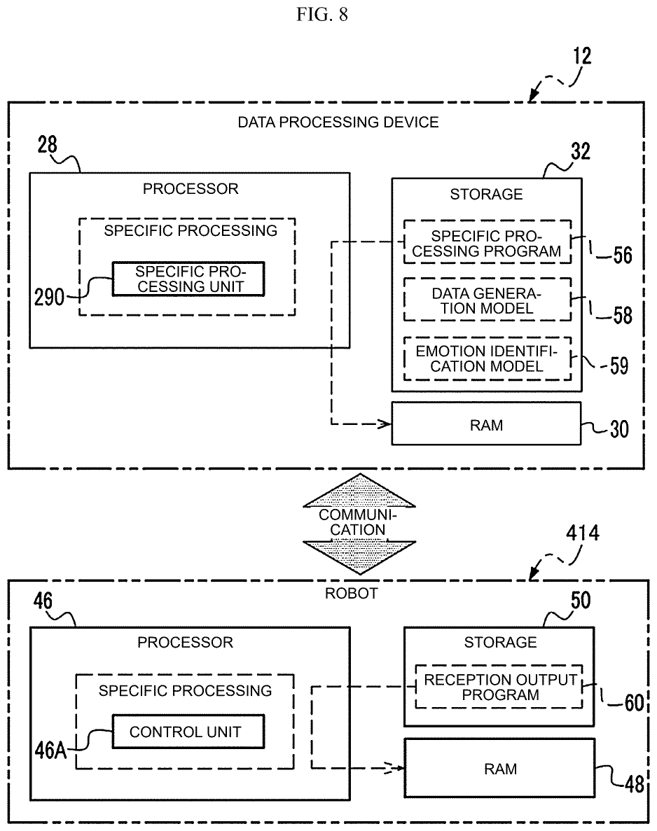

FIG. 8 shows an example of the main functions of the data processing device 12 and the robot 414. As shown in FIG. 8, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290.

In the robot 414, reception output processing is performed by the processor 46. The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48.

Next, specific processing by the specific processing unit 290 of the data processing device 12 will be described. Each part of the system described below is realized by the data processing device 12 and the robot 414. In the following description, the data processing device 12 is referred to as a “server,” and the robot 414 is referred to as a “terminal.”

(Example 1) Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the robot 414. In the robot 414, the control unit 46A causes the speaker 240 and the control target 443 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the robot 414, but it may be executed by both the specific processing unit 290 of the data processing device 12 and the control unit 46A of the robot 414. Additionally, the specific processing unit 290 of the data processing device 12 acquires or collects necessary information for processing from the robot 414 or external devices, and the robot 414 acquires or collects necessary information for processing from the data processing device 12 or external devices.

In the above embodiments, an example form where specific processing is performed by the data processing device 12 was described, but the technology disclosed herein is not limited to this, and specific processing may be performed by the robot 414.

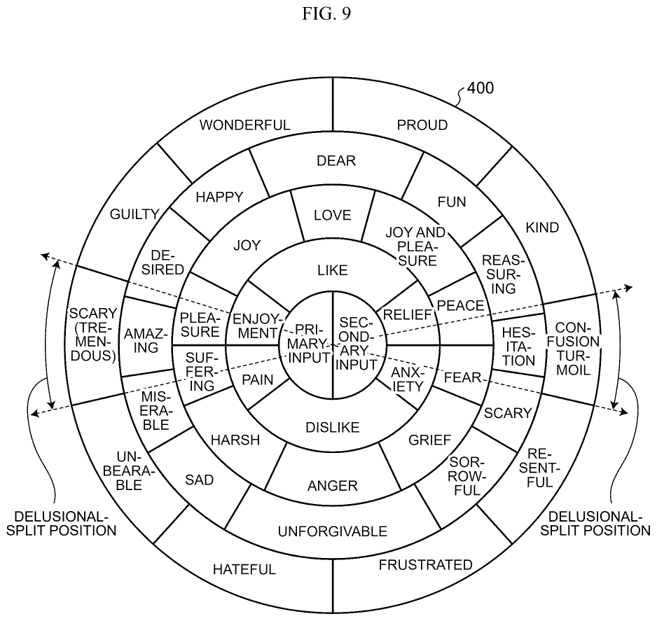

Note that the emotion identification model 59 as an emotion engine may determine the user's emotions according to a specific mapping. Specifically, the emotion identification model 59 may determine the user's emotions according to an emotion map, which is a specific mapping (see FIG. 9). Similarly, the emotion identification model 59 may determine the robot's emotions, and the specific processing unit 290 may perform specific processing using the robot's emotions.

FIG. 9 is a diagram showing an emotion map 400 where multiple emotions are mapped. In the emotion map 400, emotions are arranged concentrically radiating from the center. The closer to the center of the concentric circles, the more primitive the state of emotions is arranged. On the outer side of the concentric circles, emotions representing states and behaviors arising from mood are arranged. Emotions encompass concepts including emotional and mental states. On the left side of the concentric circles, emotions generally generated from reactions occurring in the brain are arranged. On the right side of the concentric circles, emotions generally induced by situational judgment are arranged. On the top and bottom of the concentric circles, emotions generated from reactions occurring in the brain and induced by situational judgment are arranged. Additionally, on the upper side of the concentric circles, “pleasant” emotions are arranged, and on the lower side, “unpleasant” emotions are arranged. In this way, in the emotion map 400, multiple emotions are mapped based on the structure from which emotions arise, and emotions that tend to occur simultaneously are mapped nearby.

These emotions are distributed in the 3 o'clock direction of the emotion map 400, and they usually move back and forth around reassurance and anxiety. In the right half of the emotion map 400, situational recognition takes precedence over internal sensations, giving a calm impression.

The inner side of the emotion map 400 represents the mind, and the outer side represents behavior, so the further out on the emotion map 400, the more visible (expressed in behavior) emotions become.

Here, human emotions are based on various balances like posture and blood sugar levels, and when these balances move away from the ideal, they indicate discomfort, and when they approach the ideal, they indicate comfort. In robots, cars, motorcycles, etc., emotions can be created based on various balances like posture and battery level, indicating discomfort when these balances move away from the ideal and comfort when they approach the ideal. The emotion map may be generated based on Dr. Mitsuyoshi's emotion map (Research on speech emotion recognition and brain physiological signal analysis systems related to emotions, Tokushima University, Doctoral dissertation: https://ci.nii.ac.jp/naid/500000375379). In the left half of the emotion map, emotions belonging to the domain called “reactions,” where sensations take precedence, are aligned. Additionally, in the right half of the emotion map, emotions belonging to the domain called “situations,” where situational recognition takes precedence, are aligned.

In the emotion map, two emotions that promote learning are defined. One is a negative emotion around “repentance” or “reflection” on the situation side. In other words, when a negative emotion arises in the robot, like “I never want to feel this way again” or “I don't want to be scolded again.” The other is an emotion around “desire” on the reaction side, which is positive. In other words, it is a positive feeling like “I want more” or “I want to know more.”

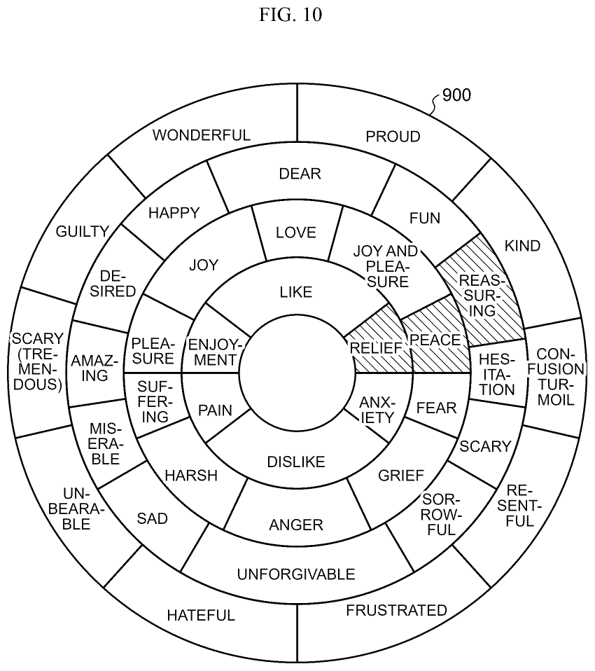

The emotion identification model 59 inputs user input into a pre-learned neural network, acquires emotion values indicating each emotion shown in the emotion map 400, and determines the user's emotions. This neural network is pre-learned based on multiple training data consisting of user input and combinations of emotion values indicating each emotion shown in the emotion map 400. Additionally, this neural network is learned so that emotions placed near each other in the emotion map 900 shown in FIG. 10 have similar values. FIG. 10 shows an example where multiple emotions like “reassured,” “calm,” and “confident” have similar emotion values.

In the above, the system according to the present disclosure has been described mainly on the functions of the data processing device 12, but the system according to the present disclosure is not necessarily mounted on a server. The system according to the present disclosure may be implemented as a general information processing system. The present disclosure may be implemented, for example, as a software program running on a personal computer, or an application running on a smartphone or the like. The method according to the present disclosure may be provided to the user in the form of SaaS (Software as a Service).

In the above embodiments, an example form where specific processing is performed by a single computer 22 was described, but the technology disclosed herein is not limited to this, and distributed processing for specific processing by multiple computers including the computer 22 may be performed. For example, the data generation model 58 may be provided in an external device of the data processing device 12, and the external device may generate data corresponding to the input data.

In the above embodiments, an example form where the specific processing program 56 is stored in the storage 32 was described, but the technology disclosed herein is not limited to this. For example, the specific processing program 56 may be stored in portable non-transitory storage media readable by a computer, such as a USB (Universal Serial Bus) memory. The specific processing program 56 stored in non-transitory storage media is installed in the computer 22 of the data processing device 12. The processor 28 executes specific processing according to the specific processing program 56.

Additionally, the specific processing program 56 may be stored in a storage device, such as a server connected to the data processing device 12 via the network 54, and downloaded and installed on the computer 22 in response to requests from the data processing device 12.

Furthermore, it is not necessary to store all of the specific processing program 56 in storage devices such as servers connected to the data processing device 12 via the network 54 or all in the storage 32, and a part of the specific processing program 56 may be stored.

Various processors, as shown next, can be used as hardware resources for executing specific processing. As processors, general-purpose processors that function as hardware resources for executing specific processing by executing software, i.e., programs, such as a CPU, can be mentioned. Additionally, as processors, dedicated electrical circuits with circuit configurations specially designed to execute specific processing, such as FPGA (Field-Programmable Gate Array), PLD (Programmable Logic Device), or ASIC (Application Specific Integrated Circuit), can be mentioned.

Each processor has a built-in or connected memory, and each processor executes specific processing using the memory.

Hardware resources for executing specific processing may be composed of one of these various processors or a combination of two or more processors of the same or different types (e.g., a combination of multiple FPGAs or a combination of a CPU and FPGA). Additionally, hardware resources for executing specific processing may be a single processor.

As an example of composing with a single processor, firstly, there is a form where one or more CPUs and software are combined to constitute a single processor, which functions as hardware resources for executing specific processing. Secondly, there is a form using a processor, such as SoC (System-on-a-chip), that realizes the function of an entire system including multiple hardware resources for executing specific processing with a single IC chip. In this way, specific processing is realized using one or more of the various processors as hardware resources.

Furthermore, as a hardware structure of these various processors, more specifically, electrical circuits combined with circuit elements such as semiconductor elements can be used. Additionally, the specific processing described above is merely one example. Therefore, it goes without saying that unnecessary steps may be deleted, new steps may be added, or the order of processing may be changed within the scope not departing from the gist.

The descriptions and drawings shown above are detailed explanations of parts related to the technology disclosed herein and are merely examples of the technology disclosed herein. For example, the explanations regarding configurations, functions, actions, and effects above are explanations regarding examples of configurations, functions, actions, and effects of parts related to the technology disclosed herein. Therefore, it goes without saying that within the scope not departing from the gist of the technology disclosed herein, unnecessary parts may be deleted, new elements may be added, or replacements may be made to the descriptions and drawings shown above. Additionally, to avoid complexity and facilitate understanding of parts related to the technology disclosed herein, explanations concerning technical common knowledge and the like that do not require special explanation for enabling the implementation of the technology disclosed herein are omitted in the descriptions and drawings shown above.

All documents, patent applications, and technical standards described in this specification are incorporated by reference to the same extent as if each document, patent application, and technical standard were specifically and individually stated to be incorporated by reference in this specification.

Note that the following supplementary notes are further disclosed regarding the above description.

### Supplementary Note 1

A system comprising: a user input unit; a generative AI processing unit; and a three-dimensional model generation unit, wherein the user input unit has a function of receiving, from a user, a plurality of requirements necessary for designing an arm or an end effector of a factory robot, such as a shape, dimensions, and weight of an object to be conveyed, a size and constraints of a work space, a gripping method, a desired material, a necessary special function, a cost upper limit, durability, and hygiene requirements; the generative AI processing unit has a function of receiving the requirements received from the user input unit as input data, comprehensively considering the object to be conveyed, the work space, the gripping method, the material, the special function, the cost, the durability, the hygiene requirements, and the like based on the requirements, automatically generating a plurality of optimal design proposals for the robot arm or the end effector, and imparting, to each of the design proposals, features reflecting the gripping method, the special function, the material, the cost, the durability, and the hygiene requirements; and the three-dimensional model generation unit automatically outputs a script for three-dimensional model generation usable in three-dimensional modeling software based on contents of a design proposal selected by the user from among the design proposals generated by the generative AI processing unit, and the script automatically generates a three-dimensional model reflecting the specified shape, dimensions, material, structure, function, special function, durability, hygiene requirements, and the like.

### Supplementary Note 2

The system according to Supplementary Note 1, wherein the generative AI processing unit automatically designs the number and arrangement of suction pads, a length and a movable range of the arm, a structure of a joint portion, a thickness of the material, an arrangement of sensors, a surface treatment, hygiene compliance, a design pattern considering cost and durability, and the like according to the shape and weight of the object to be conveyed, the constraints of the work space, the gripping method, the special function, the cost, the durability, the hygiene requirements, and the like, and the three-dimensional model generation unit outputs the script for three-dimensional model generation reflecting these detailed designs.

### Supplementary Note 3

The system according to Supplementary Note 1, wherein after the selection of the design proposal by the user, the three-dimensional model generation unit constructs the three-dimensional model by combining a plurality of basic shapes and parts based on the object to be conveyed, the work space, the gripping method, the material, the special function, the cost, the durability, the hygiene requirements, and the like, and further automatically generates the script for three-dimensional model generation reflecting a feature imparting process by the generative AI.

What is claimed is:

1. A system comprising:
circuitry configured to:
receive, via a communication interface coupled to a packet-switched network, design requirement data from a terminal device, the design requirement data comprising geometric constraint parameters, material parameters, and functional constraint parameters, and store the design requirement data in a storage device;
generate a constraint condition vector by mapping each parameter of the design requirement data to a respective dimension of a multidimensional constraint space;
generate a plurality of design proposal data records using a generative neural network model based on the constraint condition vector, each design proposal data record comprising shape parameter data, material parameter data, and structural parameter data satisfying the geometric constraint parameters and the functional constraint parameters;
generate a three-dimensional model generation script from a design proposal data record selected by a user, the three-dimensional model generation script comprising geometric construction instructions and parameter value assignments executable in three-dimensional modeling software to generate a three-dimensional model; and
transmit the plurality of design proposal data records and the three-dimensional model generation script to the terminal device via the communication interface.

2. The system according to claim 1, wherein the circuitry is configured to receive analog acoustic signal data from the terminal device, convert the analog acoustic signal data into digital waveform data, compute frequency spectrum data from the digital waveform data by fast Fourier transform, and input the frequency spectrum data to an acoustic model to decode design requirement text data, the decoded design requirement text data being included in the design requirement data.

3. The system according to claim 2, wherein the circuitry is configured to input the design requirement text data to a natural language processing model based on a transformer architecture, generate word embedding vectors from the design requirement text data, and extract geometric constraint parameters, material parameters, and functional constraint parameters from the word embedding vectors for inclusion in the constraint condition vector.

4. The system according to claim 3, wherein the circuitry is configured to receive scan data from a barcode reader or radio frequency identification reader at the terminal device, decode the scan data to extract object identification parameters and physical dimension parameters, and incorporate the object identification parameters and physical dimension parameters into the constraint condition vector as additional dimensions.

5. The system according to claim 1, wherein the circuitry is configured to distribute the constraint condition vector to a plurality of computation nodes via a load balancer, execute inference processing on the constraint condition vector in parallel across the computation nodes using graphics processing units, and aggregate inference results from the respective computation nodes to generate the plurality of design proposal data records.

6. The system according to claim 1, wherein the circuitry is configured to score each design proposal data record against a plurality of evaluation criteria comprising a structural strength metric, a cost metric, and a durability metric derived from the material parameter data and the geometric constraint parameters, and rank the plurality of design proposal data records in descending order of an aggregated evaluation score.

7. The system according to claim 6, wherein the circuitry is configured to compute the structural strength metric by applying a finite element analysis model to the shape parameter data and the material parameter data of each design proposal data record, and compare a computed stress distribution value against a maximum allowable stress threshold derived from the functional constraint parameters.

8. The system according to claim 1, wherein the circuitry is configured to generate additional structural component data for design proposal data records based on the functional constraint parameters, the additional structural component data comprising component type identifiers, positional coordinate data, and connection parameter data for inclusion in the three-dimensional model generation script.

9. The system according to claim 1, wherein the circuitry is configured to receive updated design requirement data from the terminal device via the communication interface after transmitting the plurality of design proposal data records, regenerate the constraint condition vector incorporating the updated design requirement data, and generate updated design proposal data records using the generative neural network model based on the updated constraint condition vector.

10. The system according to claim 9, wherein the circuitry is configured to store interaction history data comprising previously transmitted design proposal data records and corresponding design requirement data in the storage device, and generate the updated design proposal data records by conditioning the generative neural network model on the constraint condition vector and the interaction history data.

11. The system according to claim 1, wherein the circuitry is configured to apply a multi-objective optimization process to the plurality of design proposal data records by iteratively adjusting shape parameter data and material parameter data to minimize a cost metric and a weight metric while maintaining structural parameter data satisfying the functional constraint parameters, and update each design proposal data record with optimized parameter values.

12. The system according to claim 1, wherein the circuitry is configured to validate the three-dimensional model generation script against the constraint condition vector by executing the geometric construction instructions in a simulation environment to generate a simulated three-dimensional model, and compute a constraint satisfaction score indicating a degree to which the simulated three-dimensional model satisfies each dimension of the constraint condition vector.

13. The system according to claim 12, wherein the circuitry is configured to generate a revised three-dimensional model generation script when the constraint satisfaction score falls below a validation threshold value, the revised three-dimensional model generation script comprising updated geometric construction instructions and updated parameter value assignments derived from the optimized parameter values.

14. The system according to claim 1, wherein the circuitry is configured to store a plurality of base shape component templates in the storage device, construct the three-dimensional model generation script by combining base shape component templates selected based on the shape parameter data and the geometric constraint parameters, and insert parametric dimension values and material identifiers derived from the design proposal data record into the combined base shape component templates.

15. The system according to claim 14, wherein the circuitry is configured to retrieve base shape component templates having compatibility scores exceeding a compatibility threshold with respect to the shape parameter data from a template index stored in the storage device using similarity-based retrieval, and rank the retrieved base shape component templates by compatibility score prior to selection.

16. The system according to claim 1, wherein the circuitry is configured to distribute the plurality of computation nodes across an edge computing environment and a cloud computing environment, assign computation tasks requiring high-parameter generative model inference to cloud computation nodes, and assign preprocessing and lightweight inference tasks to edge computation nodes proximate to the terminal device.

17. The system according to claim 1, wherein the functional constraint parameters comprise gripping mechanism parameters, work space boundary parameters, material compliance parameters, and operational cycle parameters, and the three-dimensional model generation script is executable in three-dimensional modeling software to generate a three-dimensional model of an end effector component.

18. A system comprising:
circuitry configured to:
receive, via a communication interface coupled to a packet-switched network, design requirement data from a terminal device comprising geometric constraint parameters, material parameters, and functional constraint parameters received via a multimodal input interface including a voice input channel and a graphical user interface input channel;
generate a constraint condition vector by mapping each parameter of the design requirement data to a respective dimension of a multidimensional constraint space, the constraint condition vector including dimensions derived from frequency spectrum data computed from voice input and from text data extracted by a natural language processing model based on a transformer architecture;
generate a plurality of design proposal data records using a generative neural network model based on the constraint condition vector, each design proposal data record comprising shape parameter data, material parameter data, and structural parameter data;
score each design proposal data record against a structural strength metric, a cost metric, and a durability metric, and rank the plurality of design proposal data records in descending order of an aggregated evaluation score; and
generate a three-dimensional model generation script from a selected design proposal data record and transmit the three-dimensional model generation script to the terminal device via the communication interface.

19. The system according to claim 18, wherein the circuitry is configured to validate the three-dimensional model generation script by executing the geometric construction instructions in a simulation environment to compute a constraint satisfaction score, and generate a revised three-dimensional model generation script when the constraint satisfaction score falls below a validation threshold value.

20. A method comprising:
receiving, via a communication interface coupled to a packet-switched network, design requirement data from a terminal device, the design requirement data comprising geometric constraint parameters, material parameters, and functional constraint parameters, and storing the design requirement data in a storage device;
generating a constraint condition vector by mapping each parameter of the design requirement data to a respective dimension of a multidimensional constraint space;
generating a plurality of design proposal data records using a generative neural network model based on the constraint condition vector, each design proposal data record comprising shape parameter data, material parameter data, and structural parameter data satisfying the geometric constraint parameters and the functional constraint parameters;
generating a three-dimensional model generation script from a design proposal data record selected by a user, the three-dimensional model generation script comprising geometric construction instructions and parameter value assignments executable in three-dimensional modeling software to generate a three-dimensional model; and
transmitting the plurality of design proposal data records and the three-dimensional model generation script to the terminal device via the communication interface.
